(19) United States
(12) Patent Application Publication
(10) Pub. No.: US 2018/0350710 A1
(43) Pub. Date: Dec. 6, 2018

(54) SEMICONDUCTOR DEVICE, AND POWER MODULE

(71) Applicant: ROHM CO., LTD., Kyoto-shi (JP)

(72) Inventors: Seita IWAHASHI, Kyoto-shi (JP); Masao SAITO, Kyoto-shi (JP)

(21) Appl. No.: 16/055,981

(22) Filed: Aug. 6, 2018

Related U.S. Application Data
(63) Continuation of application No. PCT/JP2017/003337, filed on Jan. 31, 2017.

(30) Foreign Application Priority Data
Feb. 8, 2016 (JP) 2016-021740

(51) Int. Cl. H01L 23/31; H01L 23/00; H01L 23/29; H01L 23/373; H01L 21/56

(52) U.S. Cl. CPC H01L 23/3135; H01L 23/562; H01L 23/293; H01L 23/3121; H01L 2924/3511; H01L 24/32; H01L 21/56; H01L 2224/32225; H01L 23/3735

(57) ABSTRACT

A semiconductor device includes: a substrate; at least one semiconductor chip disposed on the substrate; a first resin layer disposed on the semiconductor chip, the first resin layer formed so as to cover the substrate and the semiconductor chip; a second resin layer disposed on the first resin layer, the second resin layer having a CTE smaller than a CTE of the first resin layer and having a coefficient of elasticity larger than a coefficient of elasticity of the first resin layer, wherein the second resin layer is formed so as to cover at least an upper surface of the first resin layer. There is provided the semiconductor device and a power module, capable of reducing a thermal resistance to improve a current density by reducing warpage of the semiconductor device, and capable of realizing cost reduction and miniaturization thereof by reducing the number of chips.

### CROSS REFERENCE TO RELATED APPLICATIONS

This is a continuation application (CA) of PCT Application No. PCT/JP2017/03337, filed on Jan. 31, 2017, which claims priority to Japan Patent Application No. P2016-021740 filed on Feb. 8, 2016 and is based upon and claims the benefit of priority from prior Japanese Patent Applications No. P2016-021740 filed on Feb. 8, 2016 and PCT Application No. PCT/JP2017/03337, filed on Jan. 31, 2017, the entire contents of each of which are incorporated herein by reference.

### FIELD

The embodiments described herein relate a semiconductor device and a power module.

### BACKGROUND

Many research institutions have been currently conducting research to develop Silicon Carbide (SiC) devices. Advantages of SiC power devices over Si power devices include low on resistance, high switching speed, high temperature operation characteristics, etc.

SiC power modules can conduct a large electric current, and can be easily operated under high temperature conditions operation, since losses produced by Si power devices are relatively smaller. However, power module design has been required for achieving such SiC power modules.

Case type packages have been used as packages of the SiC power devices.

On the other hand, there have been also disclosed semiconductor devices which are resin-sealed by means of transfermold technique.

Moreover, for conventional power modules, there has also been disclosed an example of applying two types of resins, in order to seal a semiconductor chip.

Thin type power modules have been required in respect of miniaturization of SiC power modules. Direct Bonding Copper (DBC) substrates, Direct Brazed Aluminum (DBA) substrates, Active Metal Brazed, Active Metal Bond (AMB) substrates, ceramics substrates, or the like have been used for mounting processes

### SUMMARY

The embodiments provide a semiconductor device and a power module, capable of reducing a thermal resistance to improve a current density by reducing warpage of the semiconductor device, and capable of realizing cost reduction and miniaturization thereof by reducing the number of chips.

According to one aspect of the embodiments, there is provided a semiconductor device comprising: a substrate; at least one semiconductor chip disposed on the substrate; a first resin layer disposed on the semiconductor chip, the first resin layer formed so as to cover the substrate and the semiconductor chip; and a second resin layer disposed on the first resin layer, the second resin layer having a CTE smaller than a CTE of the first resin layer and having a coefficient of elasticity larger than a coefficient of elasticity of the first resin layer, wherein the second resin layer is formed so as to cover at least an upper surface of the first resin layer.

According to another aspect of the embodiments, there is provided a power module comprising a plurality of semiconductor devices, the semiconductor device comprising: a substrate; at least one semiconductor chip disposed on the substrate; a first resin layer disposed on the semiconductor chip, the first resin layer formed so as to cover the substrate and the semiconductor chip; and a second resin layer disposed on the first resin layer, the second resin layer having a CTE smaller than a CTE of the first resin layer and having a coefficient of elasticity larger than a coefficient of elasticity of the first resin layer, wherein the second resin layer is formed so as to cover at least an upper surface of the first resin layer.

According to still another aspect of the embodiments, there is provided a power module comprising: a semiconductor device; and a cooling apparatus bonded on a lower surface of the semiconductor device via a bonding layer for cooling apparatus, wherein the semiconductor device comprises: a substrate; at least one semiconductor chip disposed on the substrate; a first resin layer disposed on the semiconductor chip, the first resin layer formed so as to cover the substrate and the semiconductor chip; and a second resin layer disposed on the first resin layer, the second resin layer having a CTE smaller than a CTE of the first resin layer and having a coefficient of elasticity larger than a coefficient of elasticity of the first resin layer, wherein the second resin layer is formed so as to cover at least an upper surface of the first resin layer.

According to yet another aspect of the embodiments, there is provided a power module comprising: a plurality of semiconductor devices; and a cooling apparatus bonded on a lower surface of the plurality of semiconductor devices via a bonding layer for cooling apparatus, wherein the semiconductor device comprises: a substrate; at least one semiconductor chip disposed on the substrate; a first resin layer disposed on the semiconductor chip, the first resin layer formed so as to cover the substrate and the semiconductor chip; and a second resin layer disposed on the first resin layer, the second resin layer having a CTE smaller than a CTE of the first resin layer and having a coefficient of elasticity larger than a coefficient of elasticity of the first resin layer, wherein the second resin layer is formed so as to cover at least an upper surface of the first resin layer.

According to a further aspect of the embodiments, there is provided a fabrication method of a semiconductor device, the fabrication method comprising: installing a substrate in a metallic mold; inserting a nested structure into the metallic mold; supplying a first resin to the metallic mold in a state where the nested structure is inserted thereinto, and forming a first resin layer so as to cover the semiconductor chip; removing the nested structure from the metallic mold; supplying a second resin to the metallic mold in a state where the nested structure is removed therefrom, and forming a second resin layer on the first resin layer so as to cover at least an upper surface of the first resin layer; and removing the metallic mold therefrom, wherein the second resin layer has a CTE smaller than a CTE of the first resin layer and has a coefficient of elasticity larger than a coefficient of elasticity of the first resin layer.

According to a still further aspect of the embodiments, there is provided a fabrication method of a power module, the fabrication method comprising: installing a substrate in a metallic mold; inserting a nested structure into the metallic mold; supplying a first resin to the metallic mold in a state where the nested structure is inserted thereinto, and forming a first resin layer so as to cover the semiconductor chip; removing the nested structure from the metallic mold; supplying a second resin to the metallic mold in a state where the nested structure is removed therefrom, and forming a second resin layer on the first resin layer so as to cover at least an upper surface of the first resin layer; removing the metallic mold therefrom; and bonding a cooling apparatus on a lower surface of the substrate via a bonding layer for cooling apparatus, wherein the second resin layer has a CTE smaller than a CTE of the first resin layer and has a coefficient of elasticity larger than a coefficient of elasticity of the first resin layer.

According to the embodiments, there can be provided the semiconductor device and the power module, capable of reducing the thermal resistance to improve the current density by reducing the warpage of the semiconductor device, and capable of realizing cost reduction and miniaturization thereof by reducing the number of chips.

### BRIEF DESCRIPTION OF DRAWINGS

FIG. 1A is a schematic cross-sectional structure diagram showing a power module having a single molding structure.

FIG. 1B is an enlarged view showing the portion A of FIG. 1A.

FIG. 1C is a schematic graphic chart showing an example of thermal resistances of structural members included in the power module shown in FIG. 1A.

FIG. 2A is a schematic cross-sectional structure diagram showing a configuration of arranging chips on a ceramics substrate, in a fabricating process of the power module having the single molding structure.

FIG. 2B is an image diagram showing the configuration shown in FIG. 2A, in the fabricating process of the power module having the single molding structure.

FIG. 3A is a schematic cross-sectional structure diagram in which the configuration shown in FIG. 2A is formed so as to be molded with a resin, in the fabricating process of the power module having the single molding structure.

FIG. 3B is an image diagram showing the power module shown in FIG. 3A, in the fabricating process of the power module having the single molding structure.

FIG. 3C is a schematic cross-sectional structure diagram showing an example in which the power module shown in FIG. 3A is warped, in the fabricating process of the power module having the single molding structure.

FIG. 4 is a schematic cross-sectional structure diagram showing an example in which a cooling apparatus is bonded to the power module shown in FIG. 3C via a bonding layer, in the fabricating process of the power module having the single molding structure.

FIG. 5A is a schematic cross-sectional structure diagram showing a power module having the single molding structure.

FIG. 5B is a schematic cross-sectional structure diagram showing a power module having a double molding structure according to the embodiments.

FIG. 6A shows a graphic chart showing an example of constituent materials of a general resin (general-purpose resins).

FIG. 6B is a schematic cross-sectional structure diagram showing an example of a general-purpose resin containing a filler.

FIG. 6C is a schematic cross-sectional structure diagram showing an example of forming the general-purpose resin shown in FIG. 6B on a copper substrate.

FIG. 7A is a schematic cross-sectional structure diagram showing an example of a single molding structure of the general-purpose resin molded on the ceramics substrate.

FIG. 7B is a schematic enlarged view of an adhesion interface between the general-purpose resin and the ceramics substrate shown in FIG. 7A.

FIG. 8A is a schematic cross-sectional structure diagram showing an example of a single molding structure of a multifiller resin molded on the ceramics substrate.

FIG. 8B is a schematic enlarged view of an adhesion interface between the multifiller resin and the ceramics substrate shown in FIG. 8A.

FIG. 9A is a schematic cross-sectional structure diagram showing an example of a single molding structure of the multifiller resin molded on the ceramics substrate.

FIG. 9B is a schematic cross-sectional structure diagram showing an example of a single molding structure of the general-purpose resin molded on the ceramics substrate.

FIG. 9C is a schematic cross-sectional structure diagram showing an example of a double molding structure of the multifiller resin and the general-purpose resin molded on the ceramics substrate.

FIG. 10 is a schematic diagram of illustrating a relationship between warpage and an adhesive force, in each of the single molding structure example of the multifiller resin, the single molding structure example of the general-purpose resin, and the double molding structure example of the multifiller resin and the general-purpose resin.

FIG. 11 is a schematic cross-sectional structure diagram showing an example of a double molding structure used for a simulation for verifying a relationship between a thickness of the resin and an amount of warping thereof.

FIG. 12 is a schematic diagram of illustrating a result of the simulation performed using the double molding structure illustrated in FIG. 11.

FIG. 13A is a schematic diagram for explaining a relationship between an amount of warping and a Coefficient of Thermal Expansion (CTE) in the single molding structure, in an example of using the general-purpose resin as the single mold.

FIG. 13B is a schematic diagram for explaining a relationship between the amount of warping and the CTE in the single molding structure, in an example of using the multifiller resin as the single mold.

FIG. 14A is a schematic diagram for explaining a down warping between the ceramics substrate and the general-purpose resin layer (lower boundary), in a schematic diagram for explaining a relationship between the amount of warping and the CTE in the double molding structure.

FIG. 14B is a schematic diagram for explaining an up warping between the general-purpose resin and the multifiller resin (upper boundary), in a schematic diagram for explaining a relationship between the amount of warping and the CTE in the double molding structure.

FIG. 14C is a schematic diagram for explaining a whole warpage of the double molding structure, in a schematic diagram for explaining a relationship between the amount of warping and the CTE in the double molding structure.

FIG. 15 is a schematic diagram for explaining an example of dimensions of a resin layer used for the double molding structure.

FIG. 16A is a schematic cross-sectional structure diagram showing a process (Phase 1) of a fabrication method of the double molding structure.

FIG. 16B is a schematic cross-sectional structure diagram showing a process (Phase 2) of the fabrication method of the double molding structure.

FIG. 16C is a schematic cross-sectional structure diagram showing a process (Phase 3) of the fabrication method of the double molding structure.

FIG. 16D is an image diagram showing a molding structure after the process illustrated in FIG. 16C.

FIG. 17A is a schematic cross-sectional structure diagram showing a process (Phase 4) of the fabrication method of the double molding structure.

FIG. 17B is a schematic cross-sectional structure diagram showing a process (Phase 5) of the fabrication method of the double molding structure.

FIG. 17C is a schematic cross-sectional structure diagram showing a process (Phase 6) of the fabrication method of the double molding structure.

FIG. 17D is an image diagram showing a molding structure after the process illustrated in FIG. 17C.

FIG. 18A is a schematic cross-sectional structure diagram showing an example of a single molding structure used for an actual measurement test for verifying a relationship between a thickness of the resin and an amount of warping thereof.

FIG. 18B is a schematic distribution chart showing an actual measurement test result of the single molding structure used for the actual measurement test for verifying the relationship between the thickness of the resin and the amount of warping thereof.

FIG. 19A is a schematic cross-sectional structure diagram showing an example of a double molding structure used for the actual measurement test for verifying the relationship between the thickness of the resin and the amount of warping thereof.

FIG. 19B is a schematic distribution chart showing an actual measurement test result of the double molding structure used for the actual measurement test for verifying the relationship between the thickness of the resin and the amount of warping thereof.

FIG. 20A is a schematic cross-sectional structure diagram showing an example of a single molding structure (multifiller resin), as a molding structure used for another simulation for verifying the relationship between the thickness of the resin and the amount of warping thereof.

FIG. 20B is a schematic cross-sectional structure diagram showing an example of a single molding structure (general-purpose resin), as a molding structure used for another simulation for verifying the relationship between the thickness of the resin and the amount of warping thereof.

FIG. 20C is a schematic cross-sectional structure diagram showing an example of a double molding structure (multifiller resin and general-purpose resin), as a molding structure used for another simulation for verifying the relationship between the thickness of the resin and the amount of warping thereof.

FIG. 21 is a schematic diagram showing a result of the simulation by means of the molding structures shown in FIG. 20.

FIG. 22A is a schematic diagram showing a result of the actual measurement test by means of the molding structures shown in FIGS. 18 to 19.

FIG. 22B is an image diagram of illustrating a measuring area for the amount of warping in the actual measurement test.

FIG. 23A is a schematic cross-sectional structure diagram for explaining thermal resistances in a power module having a single molding structure.

FIG. 23B is a schematic graphic chart of illustrating the thermal resistance of each structural member composing the power module shown in FIG. 23A.

FIG. 24A is a schematic cross-sectional structure diagram for explaining thermal resistances in a power module having a double molding structure.

FIG. 24B is a schematic graphic chart of illustrating the thermal resistance of each structural member composing the power module shown in FIG. 24A.

FIG. 25 is a schematic graphic chart of illustrating a relationship between warpage and a temperature in each of the case of using the single molding structure and the case of using the double molding structure.

FIG. 26A is a scheme cross-sectional configuration diagram of a configuration example (Example 1) of a semiconductor device according to the embodiments.

FIG. 26B is a scheme cross-sectional configuration diagram of a configuration example (Example 2) of the semiconductor device according to the embodiments.

FIG. 26C is a scheme cross-sectional configuration diagram of a configuration example (Example 3) of the semiconductor device according to the embodiments.

FIG. 26D is a scheme cross-sectional configuration diagram of a configuration example (Example 4) of the semiconductor device according to the embodiments.

FIG. 27A is a scheme cross-sectional configuration diagram of a configuration example (Example 1) of a power module according to the embodiments.

FIG. 27B is a scheme cross-sectional configuration diagram of the configuration example (Example 2) of the power module according to the embodiments.

FIG. 27C is a scheme cross-sectional configuration diagram of the configuration example (Example 3) of the power module according to the embodiments.

FIG. 27D is a scheme cross-sectional configuration diagram of the configuration example (Example 4) of the power module according to the embodiments.

FIG. 28 is a scheme cross-sectional configuration diagram showing a configuration example (Example 1) of a power module according to the embodiments including a cooling apparatus.

FIG. 29 is a scheme cross-sectional configuration diagram showing a configuration example (Example 2) of a power module according to the embodiments including the cooling apparatus.

FIG. 30 is a scheme cross-sectional configuration diagram showing a configuration example (Example 3) of a power module according to the embodiments including a cooling apparatus.

FIG. 31 is a scheme cross-sectional configuration diagram showing a configuration example (Example 4) of a power module according to the embodiments including the cooling apparatus.

FIG. 32 is a schematic planar pattern configuration diagram before forming a second resin layer, in a 2-in-1 module (module with a built-in half-bridge), in a power module according to the embodiments.

FIG. 33 is a circuit configuration diagram of a 2-in-1 module (module with the built-in half-bridge) to which an SiC Metal Insulator Semiconductor Field Effect Transistor (SiC MISFET) is applied as a semiconductor chip, in the semiconductor device according to the embodiments.

FIG. 34 is a schematic bird's-eye view configuration diagram after forming the second resin layer, in the module with the built-in half-bridge, in the semiconductor device according to the embodiments.

FIG. 35 is a schematic bird's-eye view configuration diagram after forming upper surface plate electrodes and before forming the second resin layer, in a module with the built-in half-bridge, in the semiconductor device according to the embodiments.

FIG. 36A is a schematic circuit representative diagram of the SiC MISFET of a 1-in-1 module, which is the semiconductor device according to the embodiments.

FIG. 36B is a schematic circuit representative diagram of an Insulated Gate Bipolar Transistor (IGBT) of the 1-in-1 module, in the semiconductor device according to the embodiments.

FIG. 37 is a detail circuit representative diagram of the SiC MISFET of the 1-in-1 module, which is the semiconductor device according to the embodiments.

FIG. 38A is a schematic circuit representative diagram of the SiC MISFET of the 2-in-1 module, which is the semiconductor device according to the embodiments.

FIG. 38B is a schematic circuit representative diagram of the IGBT of the 2-in-1 module, which is the semiconductor device according to the embodiments.

FIG. 39A is a schematic cross-sectional structure diagram of the SiC MISFET, which is an example of a semiconductor chip to be applied to the semiconductor device according to the embodiments.

FIG. 39B is a schematic cross-sectional structure diagram of the IGBT, which is an example of a semiconductor chip to be applied to the semiconductor device according to the embodiments.

FIG. 40 is a schematic cross-sectional structure diagram showing an SiC MISFET including a source pad electrode SP and a gate pad electrode GP, which is an example of the semiconductor chip to be applied to the semiconductor device according to the embodiments.

FIG. 41 is a schematic cross-sectional structure diagram of the IGBT including an emitter pad electrode EP and a gate pad electrode GP, which is an example of the semiconductor chip to be applied to the semiconductor device according to the embodiments.

FIG. 42 is a schematic cross-sectional structure diagram of an SiC Double Implanted MISFET (SiC DIMISFET), which is an example of a semiconductor chip which can be applied to the semiconductor device according to the embodiments.

FIG. 43 is a schematic cross-sectional structure diagram of an SiC Trench MISFET (SiC TMISFET), which is an example of a semiconductor chip which can be applied to the semiconductor device according to the embodiments.

FIG. 44A shows an example of a circuit configuration in which the SiC MISFET is applied as a semiconductor chip, and a snubber capacitor is connected between a power terminal PL and an earth terminal (ground terminal) NL, in a schematic circuit configuration of a three-phase alternating current (AC) inverter composed using the semiconductor device according to the embodiments.

FIG. 44B shows an example of a circuit configuration in which the IGBT is applied as a semiconductor chip, and the snubber capacitor is connected between the power terminal PL and the earth terminal (ground terminal) NL, in the schematic circuit configuration of a three-phase AC inverter composed using the semiconductor device according to the embodiments.

FIG. 45 is a schematic circuit configuration diagram of a three-phase AC inverter composed using the semiconductor device according to the embodiments to which the SiC MISFET is applied as a semiconductor chip.

FIG. 46 is a schematic circuit configuration diagram of a three-phase AC inverter composed using the semiconductor device according to the embodiments to which the IGBT is applied as a semiconductor chip.

### DESCRIPTION OF EMBODIMENTS

Next, the embodiments will be described with reference to drawings. In the description of the following drawings, the identical or similar reference numeral is attached to the identical or similar part. However, it should be noted that the drawings are schematic and therefore the relation between thickness and the plane size and the ratio of the thickness differs from an actual thing. Therefore, detailed thickness and size should be determined in consideration of the following explanation. Of course, the part from which the relation and ratio of a mutual size differ also in mutually drawings is included.

Moreover, the embodiments shown hereinafter exemplify the apparatus and method for materializing the technical idea; and the embodiments do not specify the material, shape, structure, placement, etc. of each component part as the following. The embodiments may be changed without departing from the spirit or scope of claims.

### Embodiments

(Power Module having Single Molding Structure)

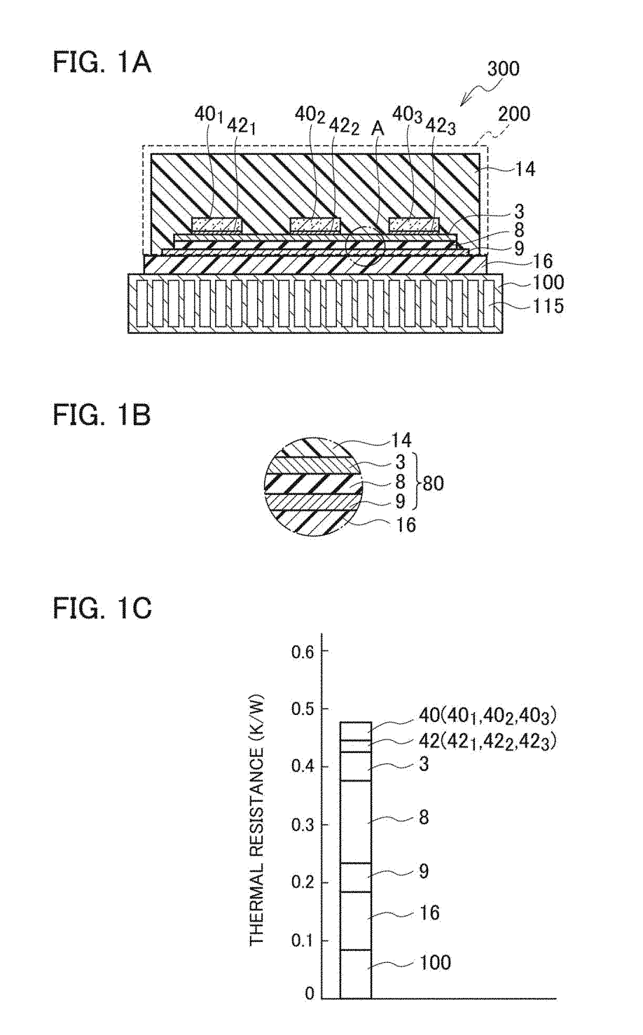

As shown in FIGS. 1A to 1B, a schematic cross-sectional structure of a power module 300 having a single molding structure includes a semiconductor device 200, and a cooling apparatus 100 bonded on a lower surface of the semiconductor device 200 via a bonding layer 16 for cooling apparatus. The semiconductor device 200 includes: a ceramics substrate 8; a copper foil (metallic frame) 3 disposed on the substrate 8; a semiconductor chip 40 (respective semiconductor chips 40₁, 40₂, 40₃) disposed on the copper foil 3 via bonding layer 42 (respective bonding layers 42₁, 42₂, 42₃) under chip; a resin layer 14 (general-purpose resin) formed on the semiconductor chip 40 (40₁, 40₂, 40₃) and the copper foil 3 to seal the semiconductor chip 40 (40₁, 40₂, 40₃); and a copper foil 9 disposed on a back side surface of the substrate 8. The cooling apparatus 100 illustrated in FIG. 1 is a water-cooling type cooling means including one or more cavity portions 115. Hereinafter, as shown in FIG. 1B, the components including the ceramics substrate 8 and the copper foils 3 and 9 respectively disposed on the upper and lower surfaces of the substrate 8 will also be generically referred to as a ceramics substrate 80.

The power module 300 as shown in FIGS. 1A to 1B is formed as an integrated module in which the semiconductor device 200 and the cooling apparatus 100 are integrated with each other, and a thickness of the bonding layer 16 for cooling apparatus formed between the semiconductor device 200 and the cooling apparatus 100 becomes a design problem. The bonding layer 16 for cooling apparatus is formed to include a thermal conduction sheet of 60 W/mK, SnAg solder of 60 W/mK, etc., for example, and the thickness of the bonding layer 16 for cooling apparatus is designed to be a thickness required in order to sufficiently absorb warpage of the semiconductor device 200.

FIG. 1C shows schematically an example of a thermal resistance of each structural member composing the power module 300 having the single molding structure, in the case of using the bonding layer 16 for cooling apparatus of which the thickness is formed to be 150 μm in order to absorb warpage of the semiconductor device 200. As illustrated in FIG. 1C, a rate of the thermal resistance of the bonding layer 16 for cooling apparatus among the whole thermal resistance of the power module 300 from the semiconductor chip 40 (40₁, 40₂, 40₃) to the cooling apparatus 100 is approximately 20%.

Accordingly, while warpage of the semiconductor device 200 is reduced, a reduction of the thermal resistance of the bonding layer 16 for cooling apparatus is required (thereby reducing the whole thermal resistance of the power module 300 from the semiconductor chip 40 (40₁, 40₂, 40₃) to the cooling apparatus 100).

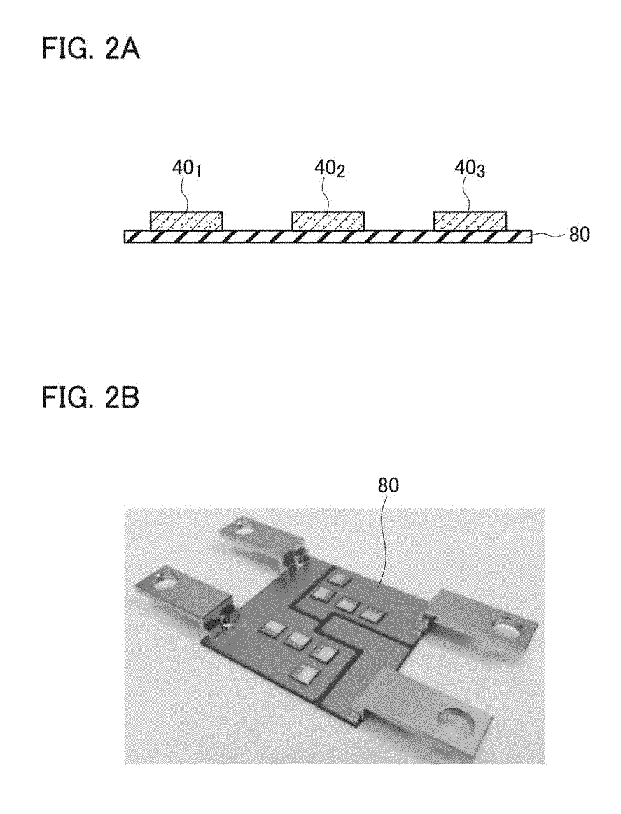

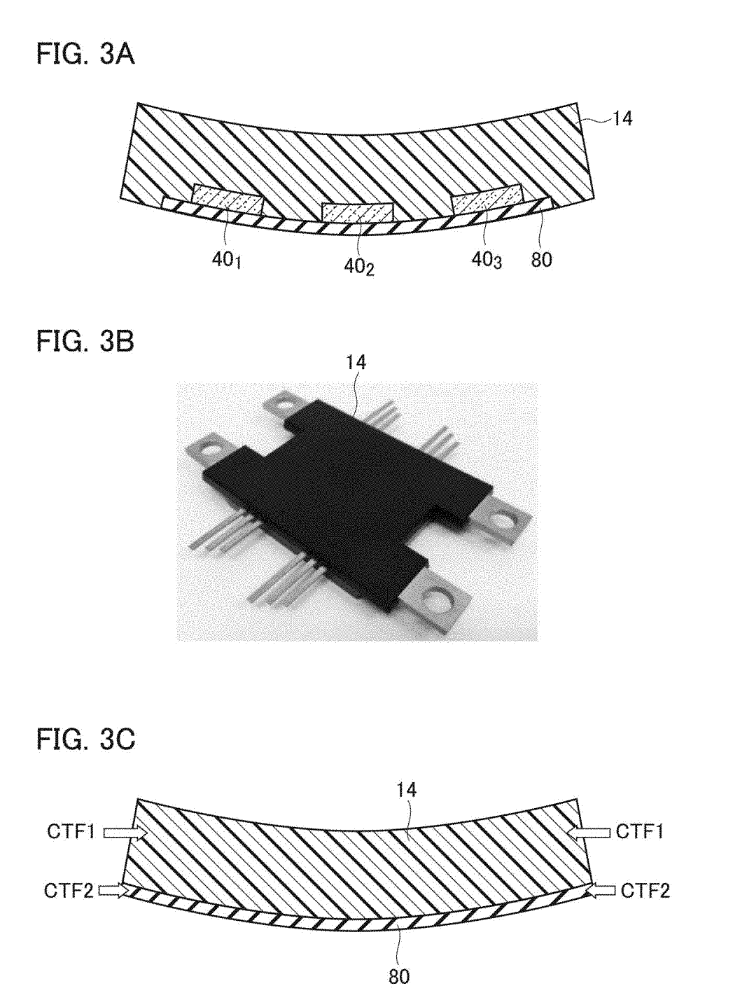

FIGS. 2 to 3 illustrate schematically a fabricating process of the power module 300 having the single molding structure.

In the fabricating process of the power module 300 having the single molding structure, firstly, the semiconductor chip 40 (40₁, 40₂, 40₃) is directly bonded on the ceramics substrate 80 as illustrated in FIGS. 2A to 2B. Subsequently, in order to seal the semiconductor chip, the semiconductor chip is molded with the resin layer 14. Then, warpage occurs in the semiconductor device 200 as illustrated in FIG. 3A.

As a factor of the warpage which occurs on the semiconductor device 200, there is listed a Coefficient of Thermal Expansion (CTE) of the resin layer 14 or ceramics substrate 80 (i.e., a shrinkage factor due to a temperature change). Since the resin layer 14 is molded under a high temperature (e.g., approximately 200° C.), structural members composing the semiconductor device 200 will be shrunk in accordance with a shrinkage factor due to a temperature change, when it is returned to room temperature. In this case, if a CTE is relatively large as that of the resin layer 14, a shrinkage factor (CTF1) thereof will become relatively large, but if a CTE (CTE) is relatively small as that of the ceramics substrate 80, the shrinkage factor (CTF2) thereof will also become relatively small. Accordingly, warpage will occur if the structural members of which the CTEs are different from each other as the resin layer 14 and the ceramics substrate 80 are closely contacted with each other.

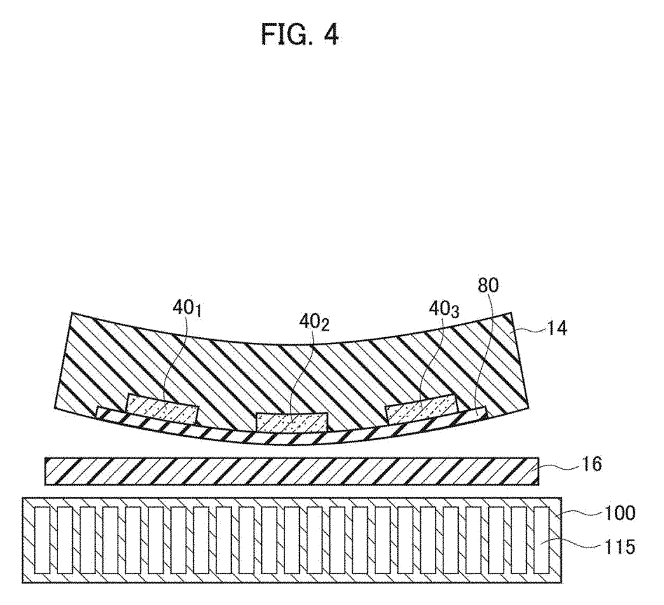

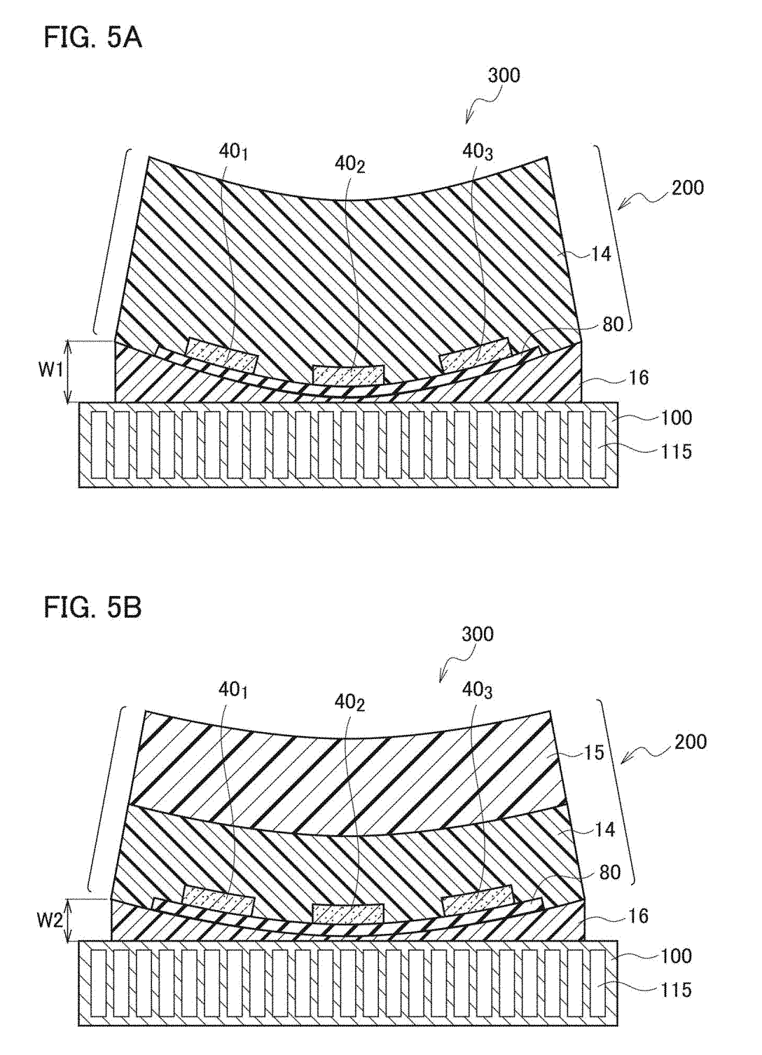

Subsequently, a relatively flat cooling apparatus 100 will be bonded to the semiconductor device 200 via the bonding layer 16 for cooling apparatus, as illustrated in FIG. 4. Accordingly, there is required the bonding layer 16 which has enough thickness (thickness according to an amount of warping W1 in an example shown in FIG. 5A) in order to absorb the warpage which occurs in the semiconductor device 200, as illustrated in FIG. 5A.

Accordingly, to reduce the warpage of the semiconductor device 200 is required, in order to further reduce the thickness of the bonding layer 16 for cooling apparatus.

### (Power Module)

As illustrated in FIG. 5B, a principal portion of a power module 300 according to the embodiments includes: a semiconductor device 200: and a cooling apparatus 100 bonded on a lower surface of the semiconductor device 200 via a bonding layer 16 for cooling apparatus. The cooling apparatus 100 illustrated in FIG. 5B is a water-cooling type cooling means including one or more cavity portions 115.

The semiconductor device 200 includes: a ceramics substrate 80; a semiconductor chip 40 (40₁, 40₂, 40₃) for power circuit composed to include a silicon carbide device, a wide-bandgap type device, etc. disposed on the ceramics substrate 80; a first resin layer 14 (e.g., general-purpose resin) disposed on the semiconductor chip 40 (40₁, 40₂, 40₃) and the ceramics substrate 80, the first resin layer 14 formed so as to cover the semiconductor chip 40 (40₁, 40₂, 40₃); and a second resin layer 15 (e.g., multifiller resin) disposed on the first resin layer 14, the second resin layer 15 having a CTE smaller than a CTE of the first resin layer 14 and having a coefficient of elasticity larger than a coefficient of elasticity of the first resin layer 14; wherein the second resin layer 15 is formed so as to cover at least an upper surface of the first resin layer 14.

The ceramics substrate 80 may include a ceramics substrate 8, and copper foils 3 and 9 disposed on upper and lower surfaces of the substrate 8, as explained with the example shown in FIG. 1B. A copper substrate 80D may be used instead of the ceramics substrate 80.

The first resin layer 14 and the second resin layer 15 are hard resins.

Moreover, the CTE of the first resin layer 14 and the CTE of the second resin layer 15 are larger than a CTE of the ceramics substrate 80 (or copper foil 3).

Moreover, a filler of 50 vol % may be used for the filler 13 contained in the first resin layer 14 and the second resin layer 15.

Moreover, the semiconductor chip 40 may be a single chip, or may be a plurality of semiconductor chips 40₁, 40₂, 40₃ as illustrated in FIG. 5B.

By using such a double molding structure of combining the first resin layer 14 with the second resin layer 15, an amount of warping (amount of warping W2 in the example shown in FIG. 5B) of the semiconductor device 200 according to the embodiments can be significantly reduced (details will be described later) compared with an amount of warping W1 in the power module having the single molding structure shown in FIG. 5A.

Moreover, a thermal resistance of the bonding layer 16 for cooling apparatus can be significantly reduced (up to 15%) by reducing the amount of warping of the semiconductor device 200 (details will be described later).

Moreover, by using the double molding structure of combining the first resin layer 14 with the second resin layer 15, a temperature of the molding can be reduced (e.g., from approximately 200° C. to approximately 180° C.), and reliability and efficiency thereof can be improved.

Consequently, since a current density can be increased, the number of chips can be reduced, and thereby the semiconductor device 200 and the power module 300 capable of realizing cost reduction and miniaturization thereof can be provided.

### (Configuration of Resin and Function of Filler)

Firstly, a configuration of a general resin (general-purpose resin) will now be explained from a viewpoint of the resin used for the first resin layer 14.

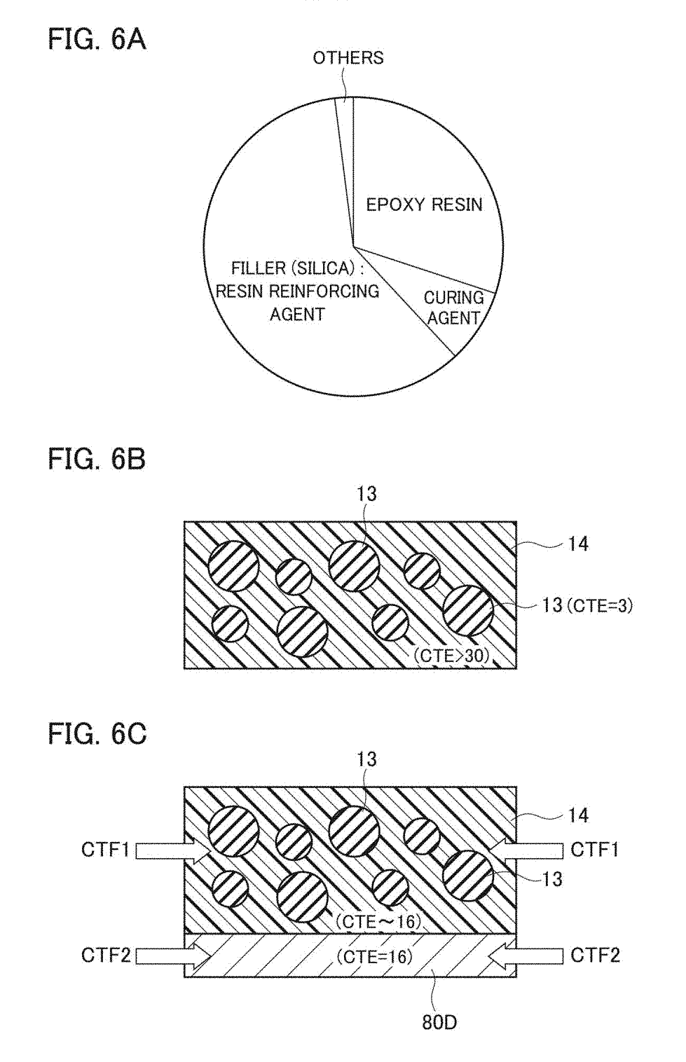

Although main materials of the resin for sealing the semiconductor chip 40 are an epoxy resin and a curing agent needed for a reaction, the SiO₂ filler 13 accounts for more than half of the materials in addition thereto, as illustrated in FIG. 6A. Since the filler 13 has a CTE smaller than the CTE of the resin, an effective CTE of the resin can be reduced by containing such a filler 13 in the resin.

Although the general resin has an extremely high CTE (equal to or more than approximately 30), an effective CTE of the first resin layer 14 can be reduced down to approximately 16 by adding to the resin a filler 13 of 56 vol % of which the CTE is relatively low as illustrated in FIG. 6B, and thereby the effective CTE of the first resin layer 14 can be made closer to the CTE (CTE=16) of the copper substrate 80D as illustrated in FIG. 6C.

Consequently, since the shrinkage factor (CTF1) of the first resin layer 14 is adjusted to the same degree of the shrinkage factor (CTF2) of the copper substrate 80D, warpage can be inhibited.

### (Warpage and Adhesive Force in Ceramics Substrate)

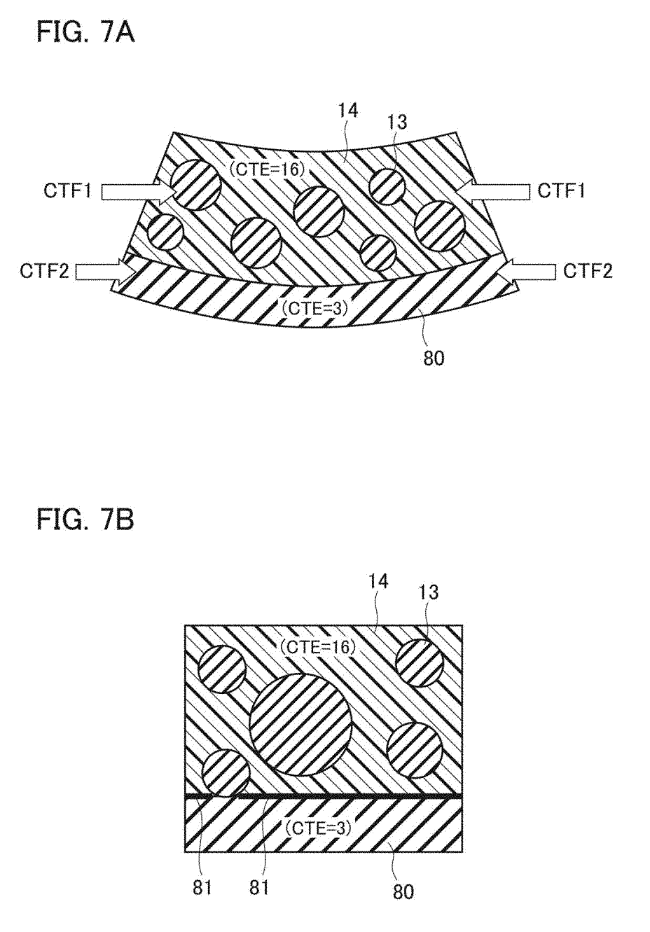

In the power module 300 according to the embodiments, a ceramics substrate as the ceramics substrate 80 is used, in order to secure insulating properties. The CTE (CTE=3) of the ceramics substrate 80 is extremely lower than the CTE (CTE=16) of the copper substrate 80D. Accordingly, a CTE difference (approximately 13) between the CTE (CTE=3) of the ceramics substrate 80 and the CTE (CTE=16) of the first resin layer 14 using the general-purpose resin is relatively large, as illustrated in FIG. 7A, and thereby an amount of warping of the semiconductor device 200 is increased (e.g., approximately 56 μm).

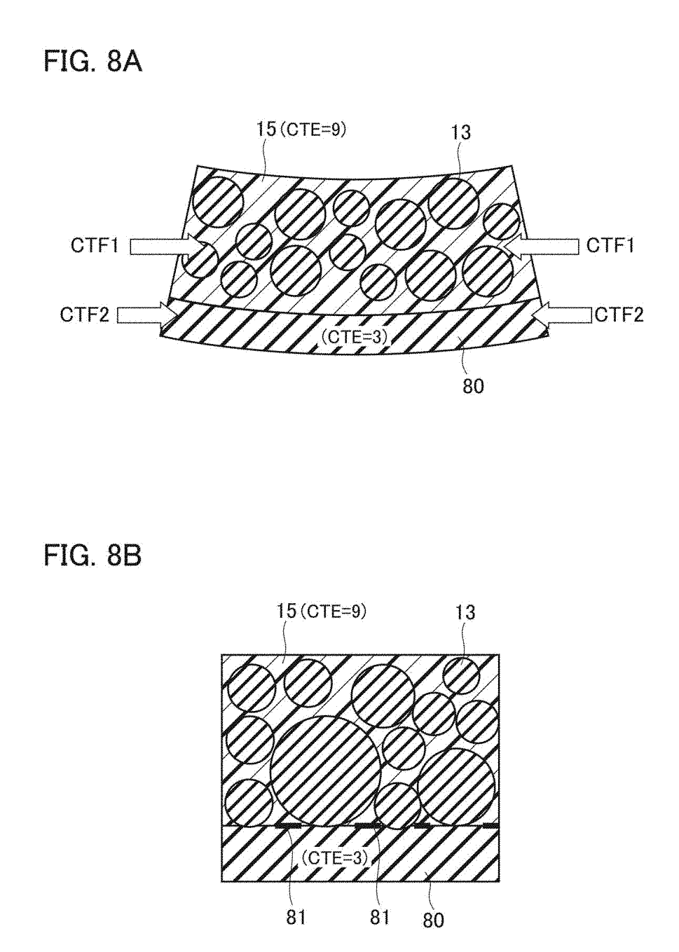

In contrast, as illustrated in FIG. 8A, although the CTE of the second resin layer 15 using the multifiller resin is approximately 9 even if adding the maximum amount of the filler 13 to the second resin layer 15, the CTE difference (approximately 6) between the CTE (CTE=3) of the ceramics substrate 80 and the CTE of the second resin layer 15 is smaller than the CTE difference with the first resin layer 14, and thereby, an amount of warping of the semiconductor device 200 is reduced (e.g., about 15 μm) compared with the case of the first resin layer 14.

On the other hand, since the filler 13 used for sealing the resin does not have a bond, an adhesion area 81 between the ceramics substrate 80 and the second resin layer 15 is reduced if there are many fillers 13, as illustrated in FIG. 8B, and thereby an adhesive force between the second resin layer 15 and the ceramics substrate 80 is reduced, and the reliability is also reduced.

In contrast, as illustrated in FIG. 7B, since an amount of the filler 13 contained in the case of the first resin layer 14 using general-purpose resin is smaller than that of the second resin layer 15, the adhesion area 81 between the ceramics substrate 80 and the first resin layer 14 is increased, and thereby the adhesive force between the first resin layer 14 and the ceramics substrate 80 is also increased, and the reliability is also improved.

### (Double Molding Structure)

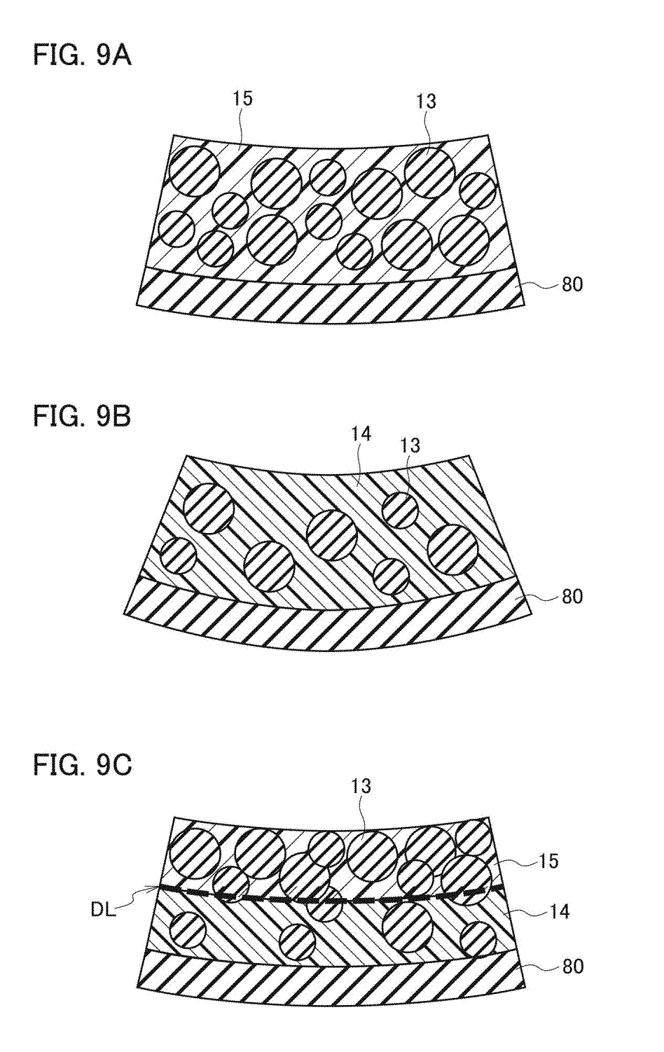

The second resin layer 15 (multifiller resin having a relatively low CTE and a relatively small amount of warping) as shown in FIG. 9A, and the first resin layer 14 (general-purpose resin of which the adhesive force is relatively high) as shown in FIG. 9B are used as the sealing resin applied to the semiconductor device 200 according to the embodiments and the power module 300.

More specifically, as illustrated in FIG. 9C, the first resin layer 14 of which the adhesive force is high is molded onto the substrate 80 side, and the second resin layer 15 having an effect of inhibiting warpage is added on an upper surface of the first resin layer 14, and thereby a trade-off between the amount of warping and the degree of adhesion can be eliminated.

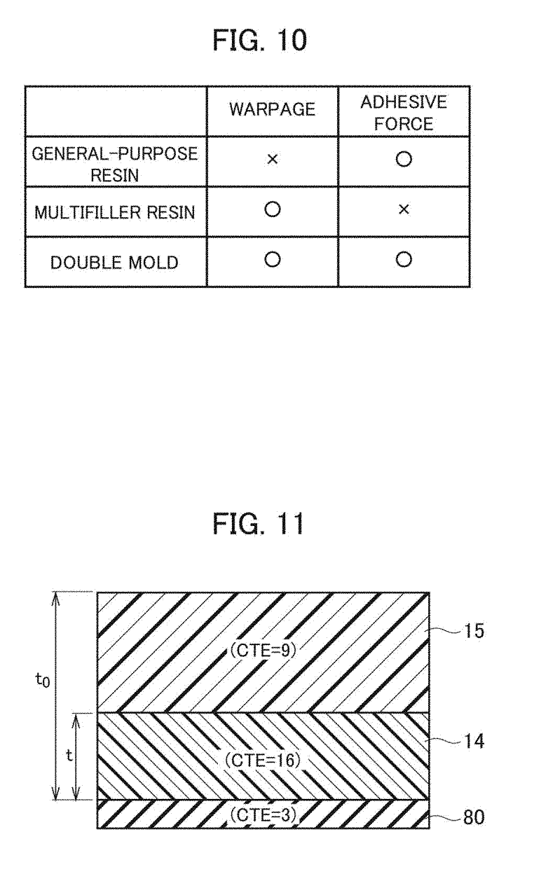

FIG. 10 schematically illustrates ◯ relationship between warpage and an adhesive force, in each of the single molding structure example of the multifiller resin, the single molding structure example of the general-purpose resin, and the double molding structure example of the multifiller resin and the general-purpose resin.

FIG. 11 schematically shows an example of a double molding structure used for a simulation for verifying a relationship between a thickness of resin and an amount of warping (i.e., for verifying a degree of a thickness of the resin capable of inhibiting warpage). As illustrated in FIG. 11, the double molding structure used for the simulation is a double molding structure in which a first resin layer 14 (CTE=16) using the general-purpose resin is formed on the ceramics substrate 80 (CTE =3) and a second resin layer 15 (CTE=9) using a multifiller resin is formed on an upper surface of the first resin layer 14.

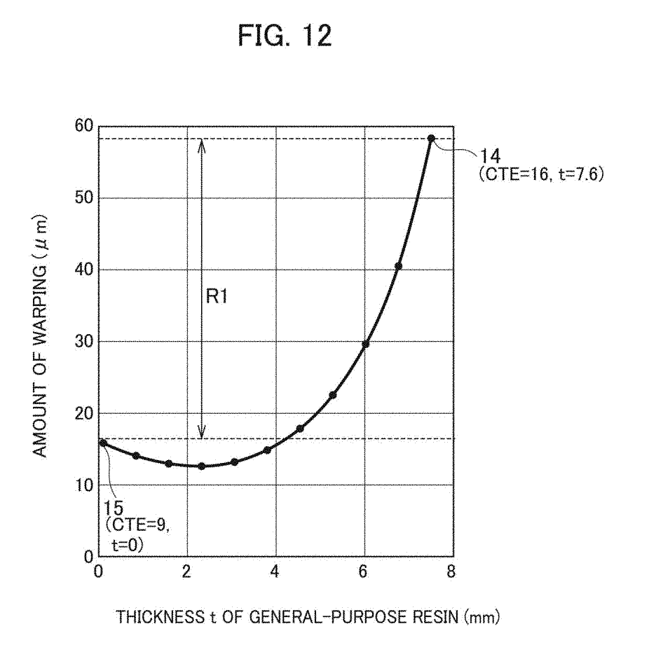

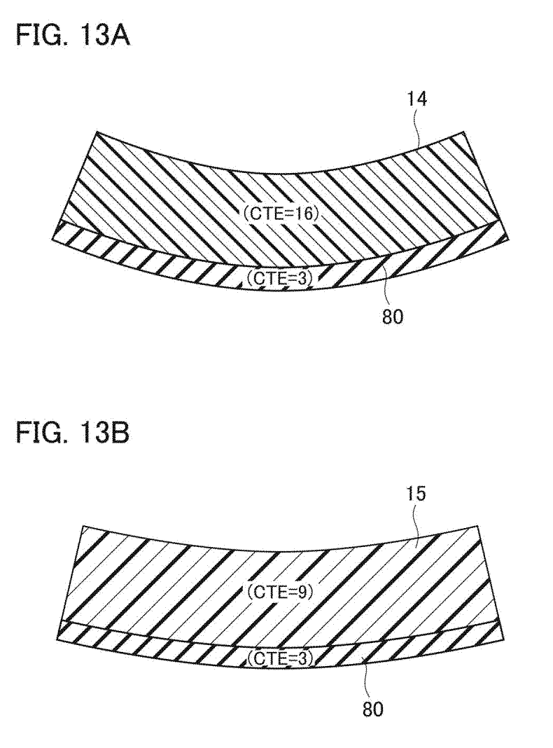

FIG. 12 schematically shows a result of the simulation for verifying a relationship between the thickness of resin and the amount of warping. In this simulation result, the horizontal axis is the thickness t (mm) of the first resin layer 14 with respect to the total resin thickness t₀=7.6 mm on the substrate of which the size is approximately 50 mm×approximately 40 mm, for example, and a vertical axis is the amount of warping. In FIG. 12, reference numeral 15 (t=0 mm) corresponds to a simulation result in the single molding structure using the multifiller resin (second resin layer 15), and reference numeral 14 (t=7.6 mm) corresponds to a simulation result in the single molding structure using the general-purpose resin (first resin layer 14).

In FIG. 12, as a result of plotting the amount of warping, the minimal value of the amount of warping in the double molding structure is obtained in a range of the thicknesses t of the first resin layer 14 is 1 mm to 3 mm. This result corresponds to a value (value by which the warpage is further inhibited) superior to the amount of warping of the simulation result in the single molding structure (the minimum value in the single molding structure) using the multifiller resin (second resin layer 15).

In the case of the single molding structure, the amount of warping is determined in accordance with a difference between the respective CTEs of the first and second resin layers 14, 15 and the CTE of the substrate 80. In this case, since the respective CTEs (CTE=9, CTE=16) of the first resin layer 14 and the second resin layer 15 are larger than the CTE of the substrate 80 (CTE =3) as illustrated in FIG. 13, it will always be warped downward.

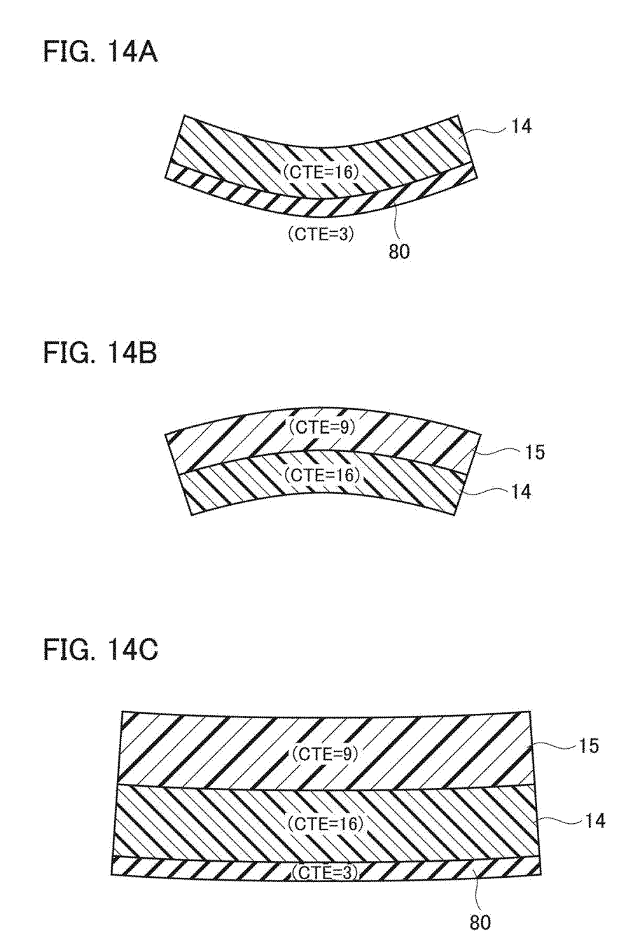

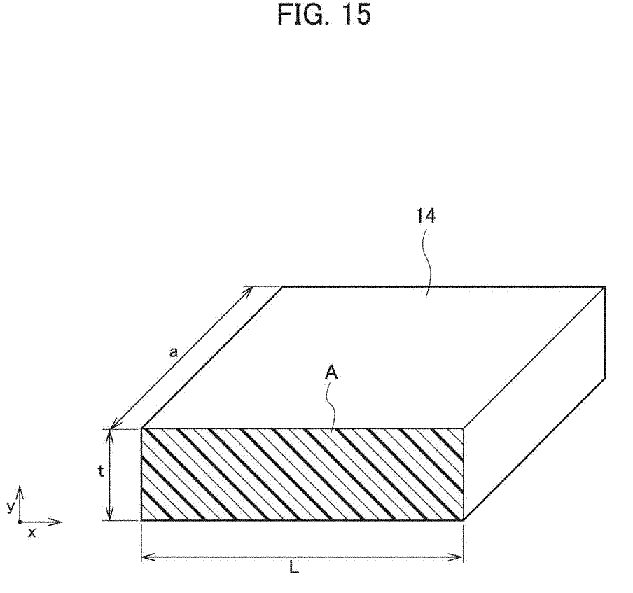

On the other hand, in the case of the double molding structure, there are two boundaries, a boundary (lower boundary) between the substrate 80 and the first resin layer 14 and a boundary (upper boundary) between the first resin layer 14 and the second resin layer 15, as illustrated in FIG. 14. Supposing that warpage occurs in each of the lower boundary and the upper boundary, the down warping occurs in the lower boundary between the substrate 80 (CTE=3) and the first resin layer 14 (CTE=16), as illustrated in FIG. 14A, but the up warping occurs in the upper boundary between the first resin layer 14 (CTE=16) and the second resin layer 15 (CTE=9) since the relationship between the CTE values is reversed from the case of the lower boundary, as illustrated in FIG. 14B.

Thus, since the effect of the up warping in the upper boundary is increased, the down warping in the lower boundary can be inhibited (FIG. 14C).

In order to improve the effect of the up warping in the upper boundary, it is necessary to consider flexural rigidity as illustrates in the formula (1) (an amount of warping is determined (such warpage can also be completely eliminated) by a balance of the flexural rigidity of each other):

Rigidity k_{B}=EI/L, Iₓ=∫_{A}y²dA=at³/12 (1)

where E is Young's modulus, L is the length, a is the width, I is the cross-sectional secondary moment, and A is the cross-sectionals area (refer to FIG. 15). Since rigidity k_{B} is in particular proportional to the cube of the thickness t, the amount of warping can be further reduced rather than that of the single molding structure by adjusting the balance of the thickness t.

### (Fabrication Method of Double Molding Structure)

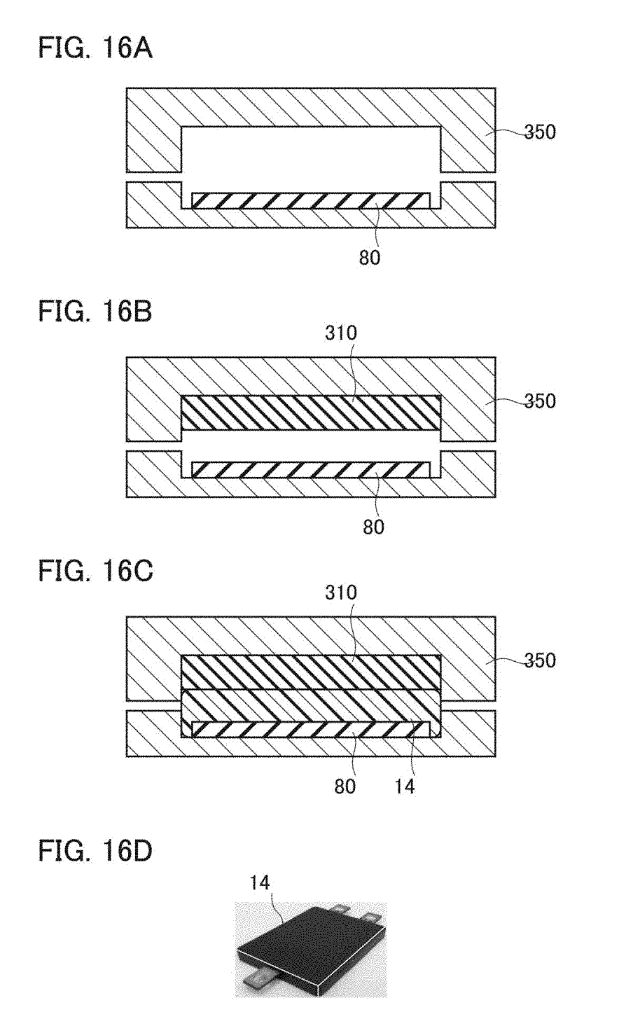

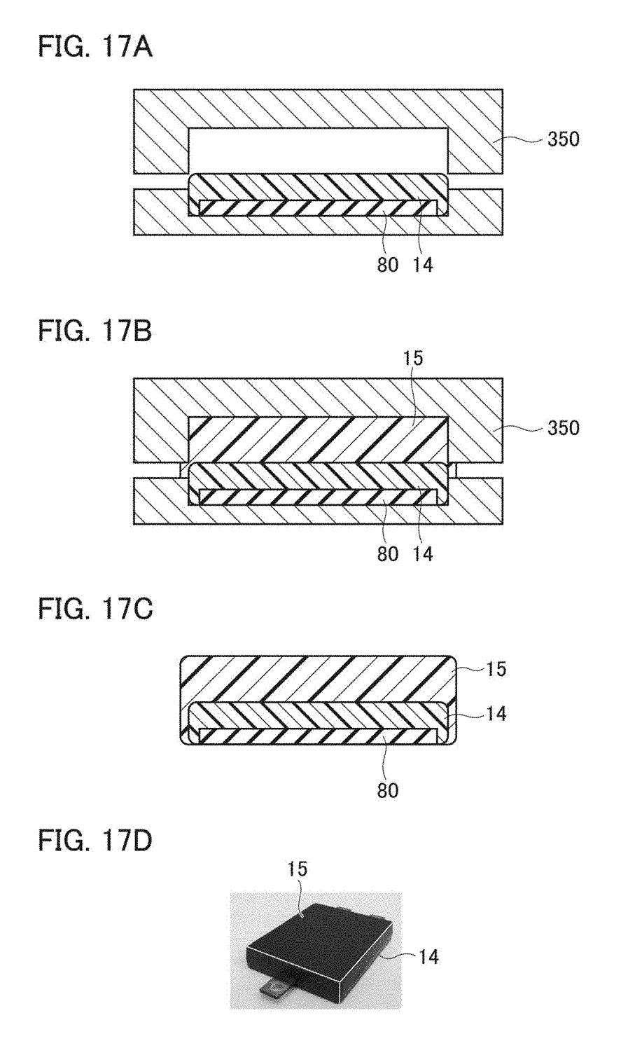

FIGS. 16 to 17 show an example of a fabrication method of a double molding structure to be applied to the semiconductor device 200 and the power module 300 according to the embodiments.

Firstly, a metallic mold 350 having nested structure capable of varying the thickness of the metallic mold is prepared, and the substrate 80 is installed in the metallic mold 350, as illustrated in FIG. 16A.

Subsequently, a general-purpose resin is supplied to the metallic mold 350 in a state where a nested structure (insert) 310 is inserted (small metallic mold) (FIG. 16B), and thereby the first resin layer 14 (e.g., the thickness of the resin is 2.5 mm) is molded (FIG. 16C). FIG. 16D is an image diagram showing a molding structure after the process illustrated in FIG. 16C.

Subsequently, a multifiller resin is supplied to the metallic mold 350 in a state where the nested structure (insert) 310 is removed (large metallic mold) (FIG. 17A), and thereby the second resin layer 15 (e.g., the thickness of the resin is 7.6 mm) is molded (FIG. 17B).

Subsequently, the metallic mold 350 is removed therefrom, and thereby a double molding structure composed including the first resin layer 14 and the second resin layer 15 can be obtained (FIG. 17C). FIG. 17D is an image diagram of a molding structure after the process of FIG. 17C.

Subsequently, the cooling apparatus 100 is bonded on the lower surface of the semiconductor device 200 sealed by the double molding structure via the bonding layer 16 for cooling apparatus, and thereby the power module according to the embodiments 300 can be obtained.

(Verification of Relationship between Thickness of Resin Layer and Amount of Warping)

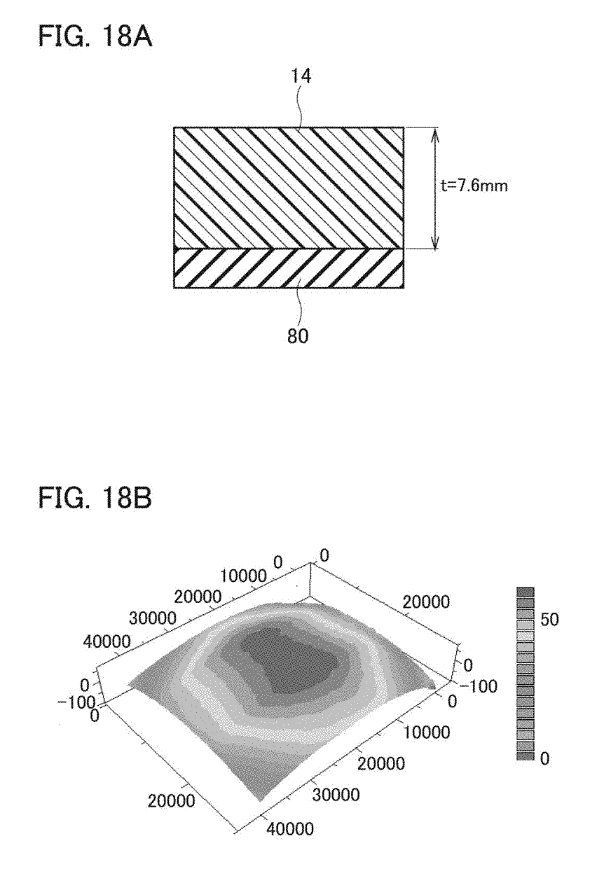

FIG. 18A schematically shows an example of a single molding structure used for an actual measurement test for verifying a relationship between a thickness of the resin and an amount of warping thereof. For example, the first resin layer 14 using the general-purpose resin (thickness t=7.6 mm) is formed on the ceramics substrate 80 with longitudinal/lateral sizes of approximately 40 mm×approximately 30 mm.

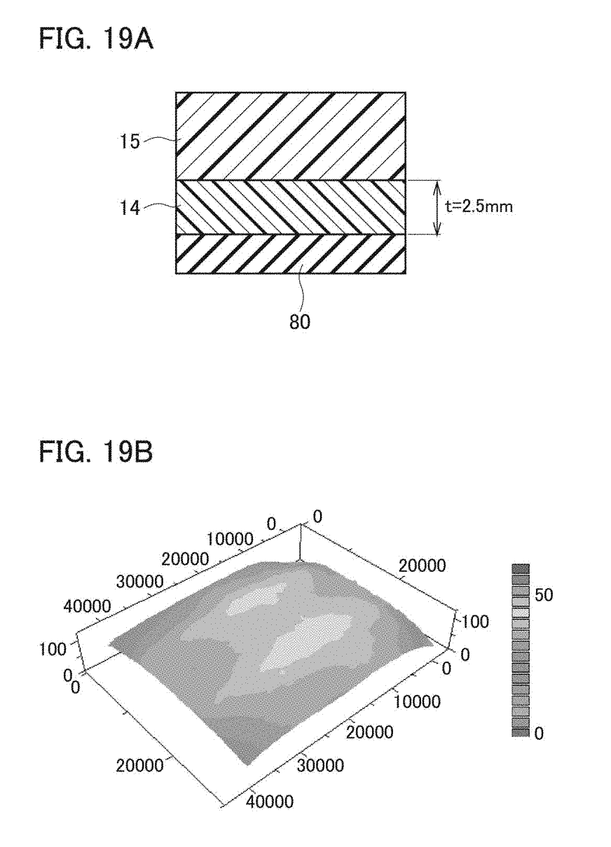

FIG. 19A schematically shows an example of a double molding structure used for the actual measurement test. The first resin layer 14 using the general-purpose resin (thickness t=2.5 mm) is formed on the ceramics substrate 80, and the second resin layer 15 using the multifiller resin is further formed on the upper surface of the first resin layer 14.

In the actual measured value (height distribution of the module) in the case of using the single molding structure shown in FIG. 18A, approximately 56-μm warpage has occurred, as shown in FIG. 18B. On the other hand, in the actual measured value (height distribution of the module) in the case of using the double molding structure of FIG. 19A, warpage is suppressed to approximately 12-μm, as shown in FIG. 19B, and a value lower than the actual measured value in the case of using the single molding structure is obtained.

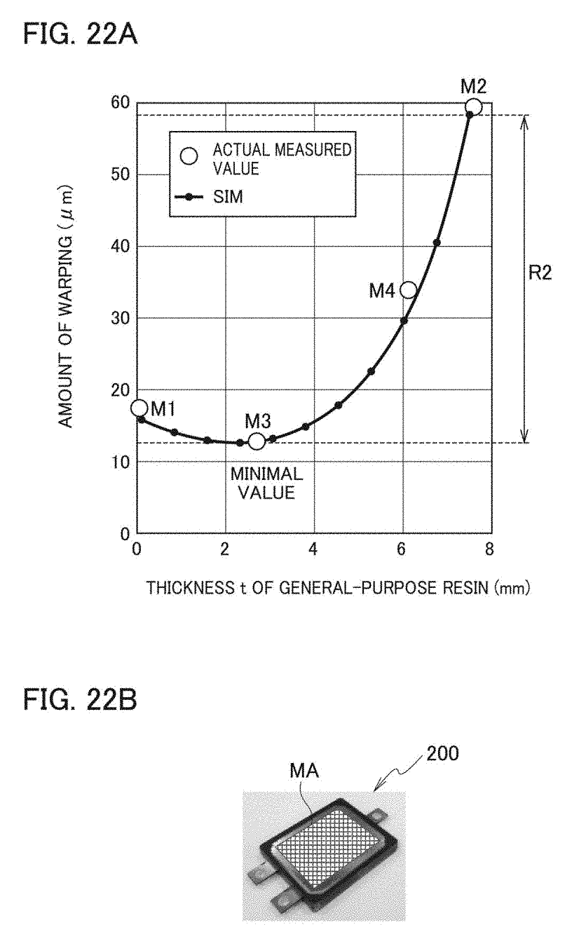

FIG. 22A is a diagram in which actual measured values M1 to M4 of the amount of warping measured by this actual measurement test are plotted on the schematic graphic chart of the simulation result (broken line) previously shown in FIG. 12. The actual measured value M1 is an actual measured value of the amount of warping which occurred in the single molding structure of the second resin layer 15 using the multifiller resin, the actual measured value M2 is an actual measured value of the amount of warping which occurred in the single molding structure (FIG. 18A) of the first resin layer 14 using the general-purpose resin, and the actual measured value M3 is an actual measured value of the amount of warping which occurred in the double molding structure (FIG. 19A) of the first resin layer 14 and the second resin layer 15. The actual measured values S1, S2 and S3 are substantially matched to the data of the simulation result (broken line) showed in FIG. 12. In addition, the actual measurement test of the single molding structure of the second resin layer 15 proves that the adhesibility between the second resin layer 15 and the substrate 80 is low.

FIG. 22B shows a measuring area MA on the power module 300 on which the amount of warping is actually measured in the aforementioned actual measurement test, and the longitudinal/lateral sizes of the measuring area MA are approximately 40 mm×approximately 50 mm.

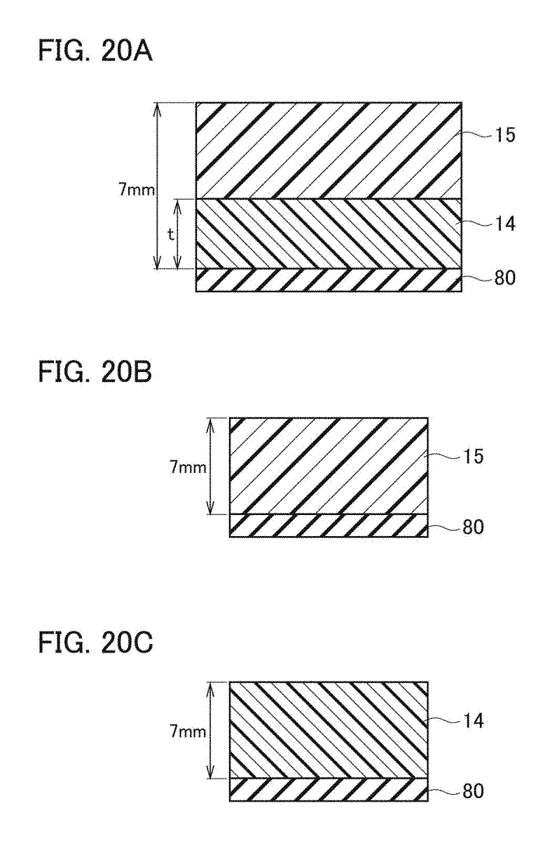

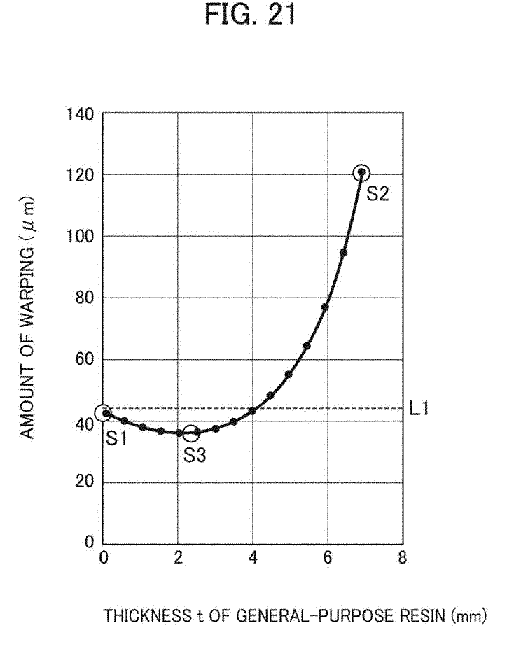

FIG. 20A schematically shows an example of a single molding structure (multifiller resin), FIG. 20B schematically shows an example of a single molding structure (general-purpose resin), and FIG. 20C schematically shows an example of a double molding structure (first resin layer 14 and second resin layer 15), as molding structures used for another simulation for verifying the relationship between the thickness of the resin and the amount of warping thereof. FIG. 21 schematically shows a result of the simulation using each molding structure shown in FIG. 20.

In this simulation, the horizontal axis is the thickness t (mm) of the first resin layer 14 with respect to the total thickness t₀ (=7 mm) of the resin, and the vertical axis is the amount of warping thereof. In FIG. 21, the point S1 (t=0) corresponds to a simulation result of the single molding structure of the multifiller resin (second resin layer 15), the point S2 (t=7) corresponds to a simulation result of the single molding structure of the general-purpose resin (first resin layer 14), and the point S3 corresponds to a simulation result of the double molding structure (first resin layer 14 and second resin layer 15). As proved from FIG. 21, as the amount of warping of the double molding structure, the minimal value (approximately 37 μm) is obtained at near the point where the thickness t of the first resin layer 14 is 2.5 mm, the minimal value obtained is also a value superior to the amount of warping in the single molding structure (approximately 42 μm: the minimum value obtained in the single molding structure) of the multifiller resin (second resin layer 15). The amount of warping in the single molding structure of the general-purpose resin (first resin layer 14) is approximately 121 μm.

### (Thermal Resistance of Power Module)

As explained above, since the thickness of the bonding layer 16 for cooling apparatus used for the power module 300 according to the embodiments can be reduced by reducing the amount of warping by means of the double molding structure, thereby the thermal resistance of the bonding layer 16 for cooling apparatus can also be reduced.

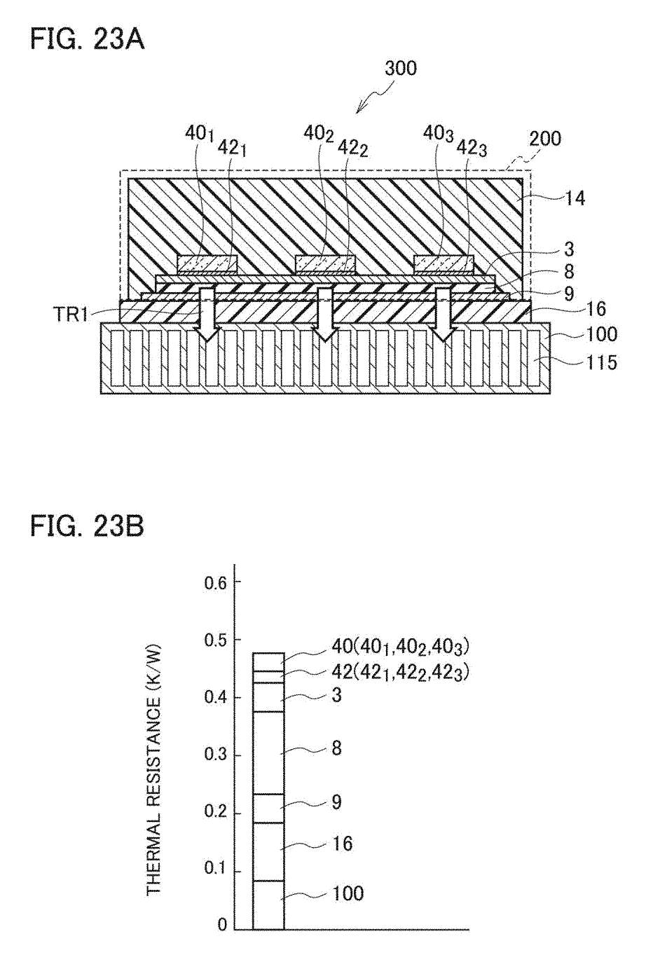

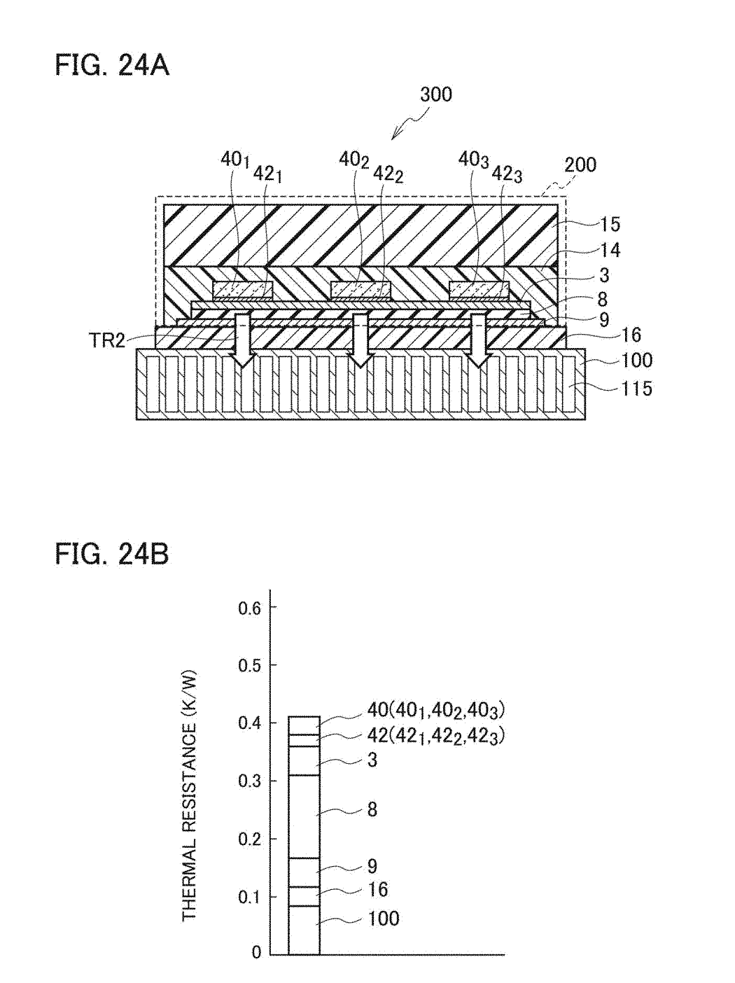

FIG. 23A is a schematic cross-sectional structure diagram for explaining thermal resistances in a power module 300 having a single molding structure, and FIG. 23B shows a schematic graphic chart of illustrating the thermal resistance of each structural member composing the power module 300 shown in FIG. 23A. FIG. 24A is a schematic cross-sectional structure diagram for explaining thermal resistances in a power module 300 having a double molding structure, and FIG. 24B is a schematic graphic chart of illustrating the thermal resistance of each structural member composing the power module 300 shown in FIG. 24A.

If the thickness of the bonding layer 16 for cooling apparatus used for the power module 300 having the single molding structure shown in FIG. 23A is 150 μm, the thickness of the bonding layer 16 for cooling apparatus used for the power module 300 having the double molding structure shown in FIG. 24A can be reduced to approximately 50 μm. Consequently, the thermal resistance TR2 of the bonding layer 16 for cooling apparatus used for the power module 300 having the double molding structure can be reduced to approximately one-third of the thermal resistance TR1 of the bonding layer 16 for cooling apparatus used for the power module 300 having the single molding structure. Accordingly, the thermal resistance of whole of the power module 300 having the double molding structure can be improved by approximately 15%.

Thus, if the thermal resistance TR2 of the bonding layer 16 for cooling apparatus is reduced to approximately ⅓, it corresponds to an impact of capable of eliminating one of six chips in power modules on which the six parallel chips are mounted, for example. Thereby, it can contribute to cost reduction and miniaturization of the power module etc.

Moreover, since the thermal resistance is reduced, it is possible to realize a stable operation, and thereby it can contribute also to high-efficiency and high reliability.

### (Temperature Characteristics of Warpage)

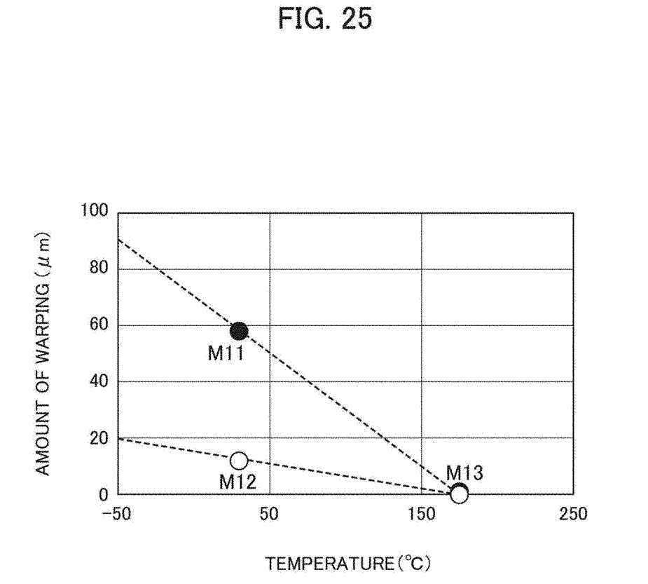

FIG. 25 is a schematic graphic chart of illustrating a relationship between warpage and a temperature in each of the case of using the single molding structure and the case of using the double molding structure used for the actual measurement test shown in FIG. 22. In FIG. 25, the point M13 corresponds to a molding temperature (175° C.: amount of warping=0 μm) of resin molding, the point M11 corresponds to an amount of warping (approximately 56 μm) in the case of using the single molding structure, and the point M12 corresponds to an amount of warping (approximately 12 μm) in the case of using the double molding structure.

As proved from FIG. 25, warpage is changed in accordance with temperatures, an amount of warping in the case of using the single molding structure is zero at a molding temperature (175° C.) but is approximately 56 μm at the room temperature. In the case of general power modules etc., an operation compensation from a view point of reliability to approximately −50° C. is required. However, if the single molding structure is used, approximately 100-μm warpage which is approximately twice as large as that under the room temperature occurs at the temperature of −50° C. Accordingly, considering an approximately 1.5-time design margin, a thickness of approximately 150 μm of the bonding layer 16 for cooling apparatus in the case of using the single molding structure is required in order to absorb the warpage of approximately 150 μm.

On the other hand, it is supposed that an amount of warping in the case of using the double molding structure is approximately 12 μm at the room temperature, and is approximately 20 μm also at 50° C. Accordingly, even considering the approximately 1.5-time design margin, the thickness of the bonding layer 16 for cooling apparatus in the case of using the double molding structure is set as approximately 50 μm capable of absorbing nearly warpage of 50 μm.

### (Configuration Examples of Semiconductor Device)

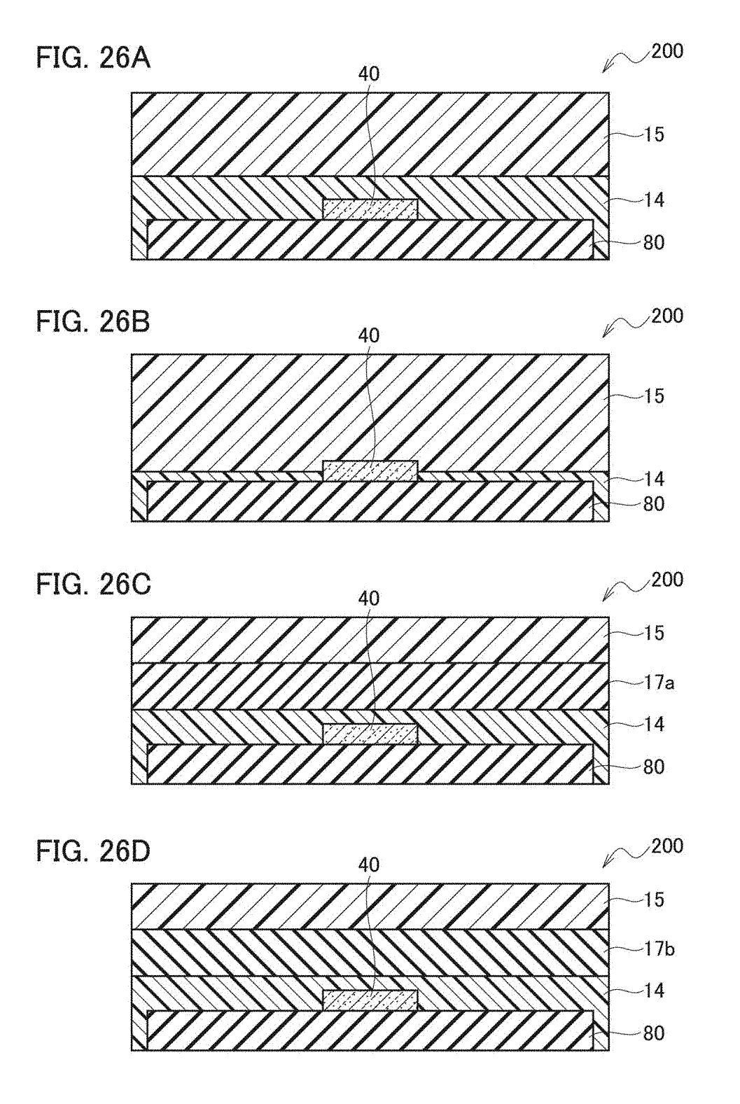

As illustrated in FIG. 26A, a configuration example (Example 1) of the semiconductor device 200 according to the embodiments includes: a ceramics substrate 80; a single semiconductor chip 40 disposed on the ceramics substrate 80; a first resin layer 14 (e.g., general-purpose resin) disposed on the semiconductor chip 40, the first resin layer 14 formed so as to cover the ceramics substrate 80 and the semiconductor chip 40; and a second resin layer 15 (e.g., multifiller resin) disposed on the first resin layer 14, the second resin layer 15 having a coefficient of elasticity larger than a coefficient of elasticity of the first resin layer 14 and having a CTE smaller than a CTE of the first resin layer 14; wherein the second resin layer 15 is formed so as to cover at least an upper surface of the first resin layer 14.

As illustrated in FIG. 26B, in a configuration example (Example 2) of the semiconductor device 200 according to the embodiments, the thickness of the first resin layer 14 is formed so as to be thinner than that of the configuration example (Example 1) shown in FIG. 26A. In the example shown in FIG. 26B, the thickness of the first resin layer 14 is formed so as to be lower than the height of the semiconductor chip 40. Moreover, since the thickness of the first resin layer 14 is thinner, the thickness of the second resin layer 15 is increased so that the thickness of the whole double molding structure is formed to be the same as that of the configuration example (Example 1).

In a configuration example (Example 3) of the semiconductor device 200 according to the embodiments, a third resin layer 17a is inserted between the first resin layer 14 and the second resin layer 15, as illustrated in FIG. 26C. A CTE of the third resin layer 17a is smaller than the CTE of the first resin layer 14 but is larger than the CTE of the second resin layer 15. Moreover, a coefficient of elasticity of the third resin layer 17a is larger than the coefficient of elasticity of the first resin layer 14 but is smaller than the coefficient of elasticity of the second resin layer 15.

In a configuration example (Example 4) of the semiconductor device 200 according to the embodiments, a fourth resin layer 17b is inserted between the first resin layer 14 and the second resin layer 15, as illustrated in FIG. 26D. The fourth resin layer 17b contains a resin in which a resin (e.g., resin used for the first resin layer 14) having a relatively high CTE is mixed with a resin (e.g., resin used for the second resin layer 15) having a relatively low CTE. A CTE of the fourth resin layer 17b is smaller than the CTE of the first resin layer 14 but is larger than the CTE of the second resin layer 15. Moreover, a coefficient of elasticity of the fourth resin layer 17b is larger than the coefficient of elasticity of the first resin layer 14 but is smaller than the coefficient of elasticity of the second resin layer 15.

In the configuration examples (Examples 1 to 4) of the semiconductor device 200 according to the embodiments, although the examples of mounting the single semiconductor chip 40 are shown, the number of the semiconductor chips 40 to be mounted is not limited to the aforementioned examples, but two or more semiconductor chips 40 may be mounted as required.

### (Configuration Examples of Power Module)

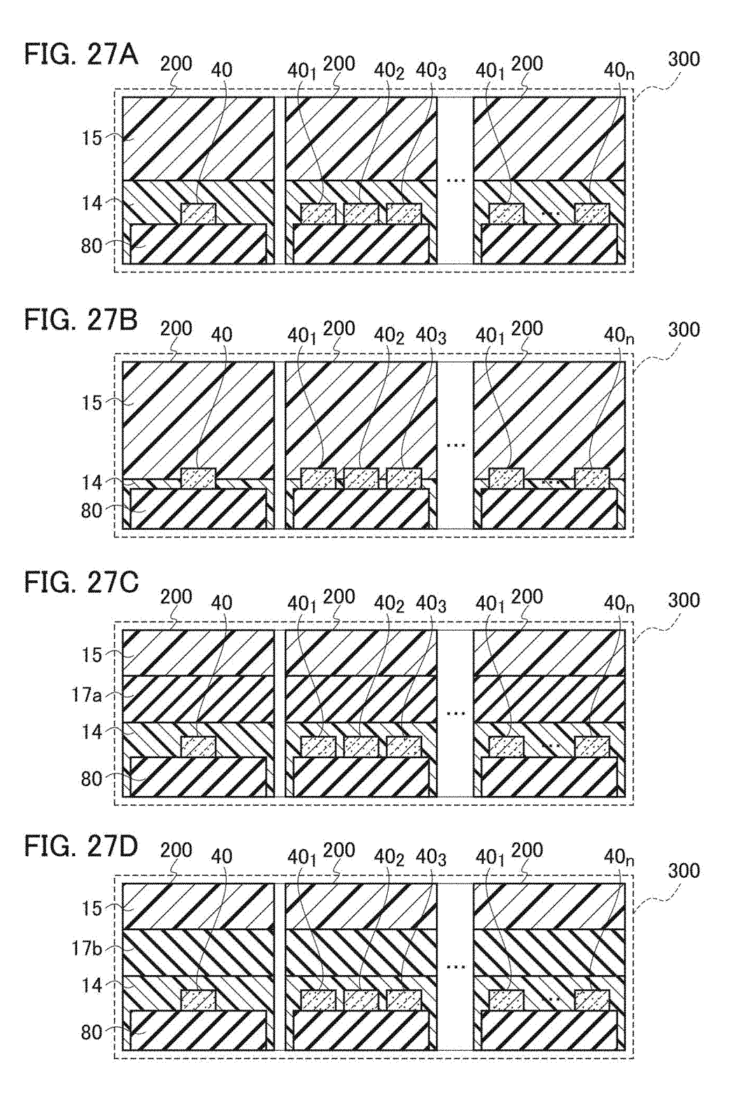

A configuration example (Example 1) of the power module 300 according to the embodiments is a power module 300 including a plurality of semiconductor devices 200, as illustrated in FIG. 27A. More specifically, each of the plurality of the semiconductor devices 200 (n semiconductor devices in an example shown in FIG. 27A) includes: a ceramics substrate 80; at least one semiconductor chip 40 (40₁, 40₂, 40₃, . . . , 40ₙ) disposed on the ceramics substrate 80; a first resin layer 14 (e.g., general-purpose resin) disposed on the semiconductor chip 40 (40₁, 40₂, 40₃, . . . , 40ₙ), the first resin layer 14 formed so as to cover the ceramics substrate 80 and the semiconductor chip 40 (40₁, 40₂, 40₃, . . . , 40ₙ); a second resin layer 15 (e.g., multifiller resin) disposed on the first resin layer 14, the second resin layer 15 having a coefficient of elasticity larger than a coefficient of elasticity of the first resin layer 14 and having a CTE smaller than a CTE of the first resin layer 14; wherein the second resin layer 15 is formed so as to cover at least an upper surface of the first resin layer 14. Each semiconductor device 200 is integrally housed in a case or the like (not illustrated).

The example of the power module 300 shown in FIG. 27A includes: the semiconductor device 200 including a single semiconductor chip 40; the semiconductor device 200 including three semiconductor chips 40₁, 40₂, 40₃; and the semiconductor device 200 including n semiconductor chips 40₁, 40₂, 40₃, . . . , 40ₙ. However, the number of the semiconductor chips 40 mounted in each semiconductor device 200 is not limited to the example shown in FIG. 27A, but the semiconductor devices 200 respectively may mount the required number of the semiconductor chips 40.

As illustrated in FIG. 27B, in a configuration example (Example 2) of the power module 300 according to the embodiments, the thickness of the first resin layer 14 of each semiconductor device 200 is formed so as to be thinner than that of the configuration example (Example 1) shown in FIG. 27A. In the example shown in FIG. 27B, the thickness of the first resin layer 14 is formed so as to be lower than the height of the semiconductor chip 40. Moreover, since the thickness of the first resin layer 14 is thinner, the thickness of the second resin layer 15 is increased so that the thickness of the whole double molding structure is formed to be the same as that of the configuration example (Example 1) shown in FIG. 27A.

In the example of the power module 300 shown in FIG. 27B, although the thickness of the first resin layer 14 and the thickness of the second resin layer 15 are respectively made uniform, the thicknesses may be changed for every semiconductor device 200 as required.

In a configuration example (Example 3) of the power module 300 according to the embodiments, a third resin layer 17a is inserted between the first resin layer 14 and the second resin layer 15 in each semiconductor device 200, as illustrated in FIG. 27C. A CTE of the third resin layer 17a is smaller than the CTE of the first resin layer 14 but is larger than the CTE of the second resin layer 15. Moreover, a coefficient of elasticity of the third resin layer 17a is larger than the coefficient of elasticity of the first resin layer 14 but is smaller than the coefficient of elasticity of the second resin layer 15.

In the example of the power module 300 shown in FIG. 27C, although the thickness of the first resin layer 14, the thickness of the second resin layer 15 and the thickness of the third resin layer 17a are respectively made uniform, the thicknesses may be changed for every semiconductor device 200 as required. Moreover, the CTE and the coefficient of elasticity of each layer may also be changed for every semiconductor device 200 as required. A semiconductor device(s) 200 including no third resin layer 17a may be included in the power module 300.

In a configuration example (Example 4) of the power module 300 according to the embodiments, a fourth resin layer 17b is inserted between the first resin layer 14 and the second resin layer 15 in each semiconductor device 200, as illustrated in FIG. 27D. The fourth resin layer 17b contains a resin in which a resin (e.g., resin used for the first resin layer 14) having a relatively high CTE is mixed with a resin (e.g., resin used for the second resin layer 15) having a relatively low CTE. A CTE of the fourth resin layer 17b is smaller than the CTE of the first resin layer 14 but is larger than the CTE of the second resin layer 15. Moreover, a coefficient of elasticity of the fourth resin layer 17b is larger than the coefficient of elasticity of the first resin layer 14 but is smaller than the coefficient of elasticity of the second resin layer 15.

In the example of the power module 300 shown in FIG. 27D, although the thickness of the first resin layer 14, the thickness of the second resin layer 15 and the thickness of the fourth resin layer 17b are respectively made uniform, the thicknesses may be changed for every semiconductor device 200 as required. Moreover, the CTE and the coefficient of elasticity of each layer may also be changed for every semiconductor device 200 as required. Moreover, a semiconductor device(s) 200 including no fourth resin layer 17b may be included in the power module 300.

(Configuration Example of Power Module including Cooling Apparatus)

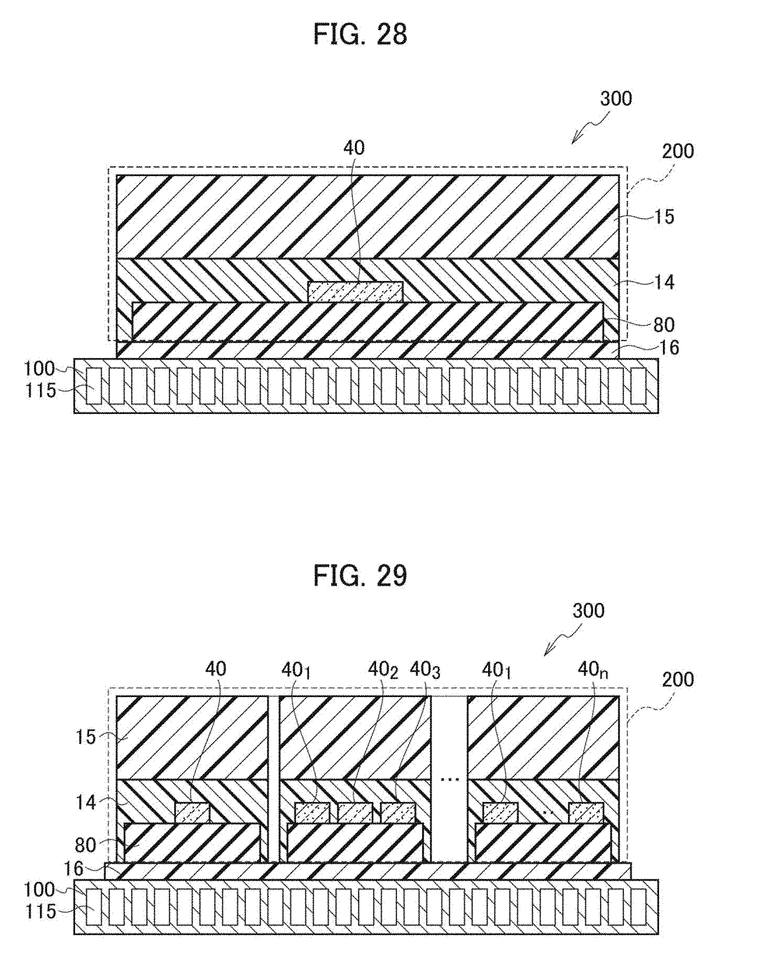

As illustrated in FIG. 28, in a configuration example (Example 1) of the power module 300 according to the embodiments configured to include a cooling apparatus 100, the power module 300 includes: a semiconductor device 200; and a cooling apparatus 100 bonded on a lower surface of the semiconductor device 200 via a bonding layer 16 for cooling apparatus. The cooling apparatus 100 illustrated in FIG. 28 is a water-cooling type cooling means including one or more cavity portions 115. Moreover, a configuration of the semiconductor device 200 is the same as that of the configuration example (Example 1) of the semiconductor device 200 shown in FIG. 26A, and therefore a detailed description thereof is omitted.

In addition, the configuration example (Example 1) of the power module 300 according to the embodiments may include a semiconductor device 200 having the same configuration as that of the semiconductor device 200 shown in FIGS. 26B to 26D.

As illustrated in FIG. 29, in a configuration example (Example 2) of the power module 300 according to the embodiments configured to include a cooling apparatus 100, the power module 300 includes: a plurality of semiconductor devices 200; and a cooling apparatus 100 bonded on lower surfaces of the plurality of the semiconductor devices 200 via a bonding layer 16 for cooling apparatus. Since the cooling apparatus 100 illustrated in FIG. 29 is the same as the cooling apparatus 100 shown in FIG. 28 and the configuration of the plurality of the semiconductor devices 200 is the same as those of the plurality of the semiconductor devices 200 included in the configuration example (Example 1) of the power module 300 shown in FIG. 27A, the detailed description thereof is omitted.

The configuration example (Example 2) of the power module 300 may also include semiconductor devices 200 having the same configuration group as that of the plurality of the semiconductor devices 200 included in each power module 300 shown in FIGS. 27B to 27D.

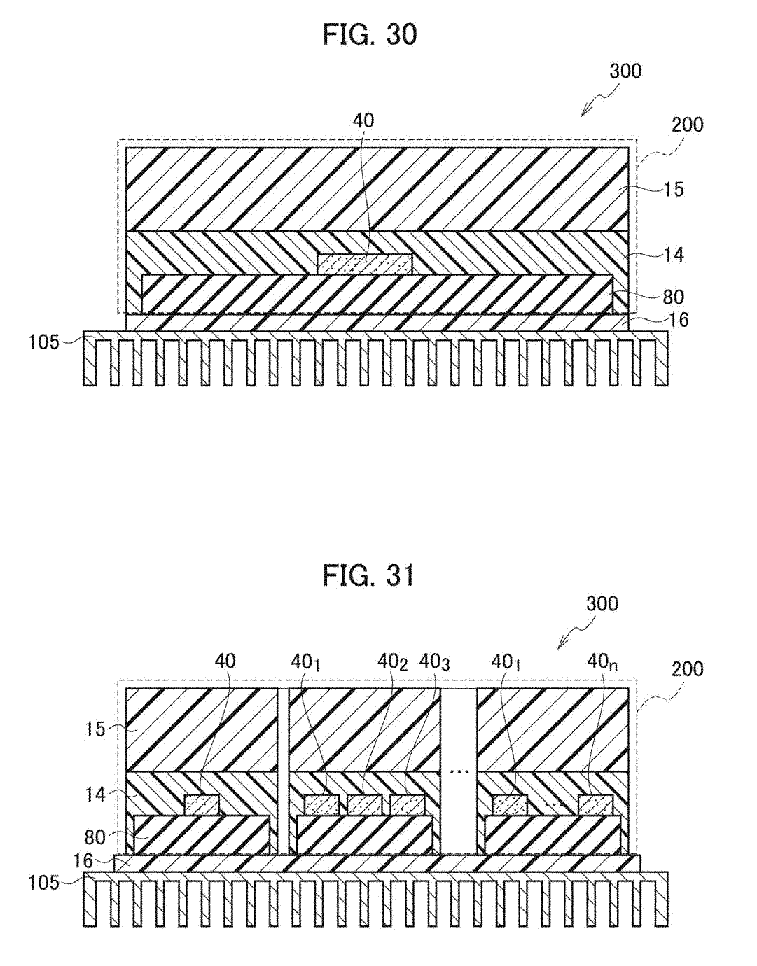

As illustrated in FIG. 30, in a configuration example (Example 3) of the power module 300 according to the embodiments configured to include a cooling apparatus 100, the power module 300 includes: a semiconductor device 200; and a cooling apparatus 105 bonded on a lower surface of the semiconductor device 200 via a bonding layer 16 for cooling apparatus. The cooling apparatus 105 illustrated in FIG. 30 is an air-cooling type cooling means including one or more cooling fins. Moreover, a configuration of the semiconductor device 200 is the same as that of the configuration example (Example 1) of the semiconductor device 200 shown in FIG. 26A, and therefore a detailed description thereof is omitted.

In addition, the configuration example (Example 3) of the power module 300 may also include semiconductor devices 200 having the same configuration group as that of the plurality of the semiconductor devices 200 included in each power module 300 shown in FIGS. 26B to 26D.

As illustrated in FIG. 31, in a configuration example (Example 4) of the power module 300 according to the embodiments configured to include a cooling apparatus 100, the power module 300 includes: a plurality of semiconductor devices 200; and a cooling apparatus 105 bonded on lower surfaces of the plurality of the semiconductor devices 200 via a bonding layer 16 for cooling apparatus. The cooling apparatus 105 illustrated in FIG. 31 is the same as the cooling apparatus 105 shown in FIG. 30 and the configuration of the plurality of the semiconductor devices 200 is the same as those of the plurality of the semiconductor devices 200 included in the configuration example (Example 1) of the power module 300 shown in FIG. 27A.

In addition, the configuration example (Example 4) of the power module 300 may also include semiconductor devices 200 having the same configuration group as that of the plurality of the semiconductor devices 200 included in each power module 300 shown in FIGS. 27B to 27D.

### (Detail Configuration Examples of Semiconductor Device and Semiconductor Chip)

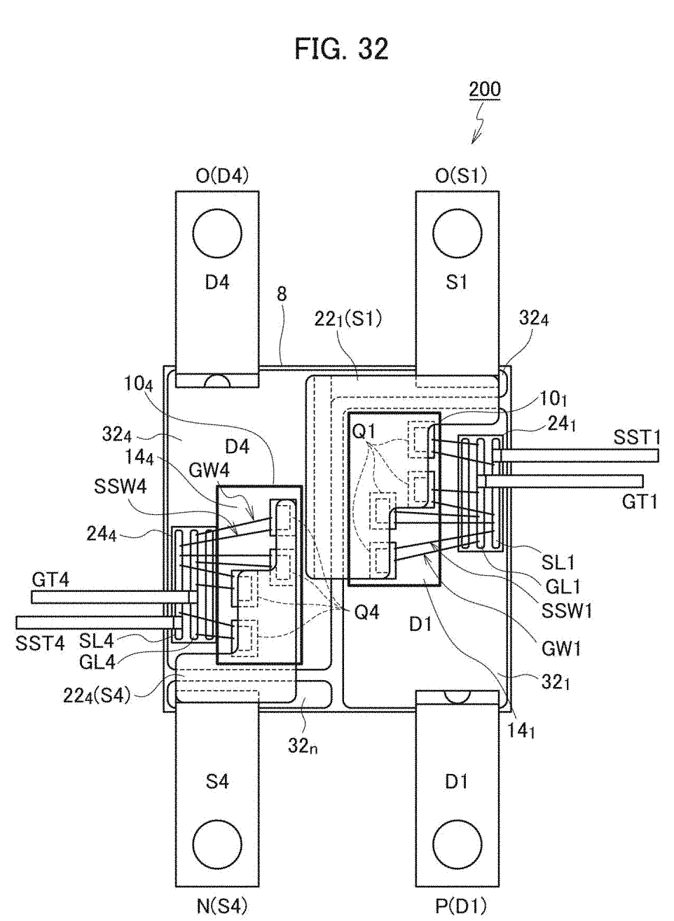

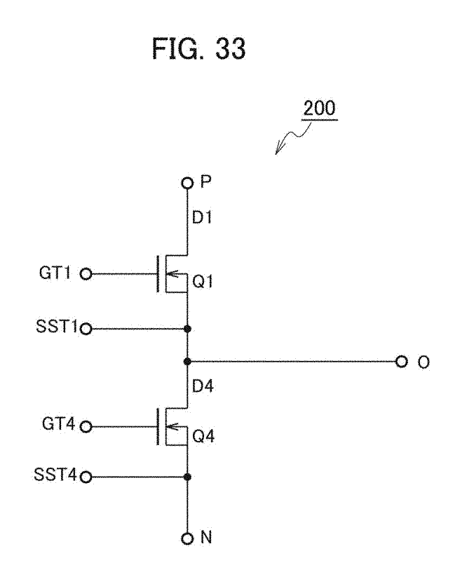

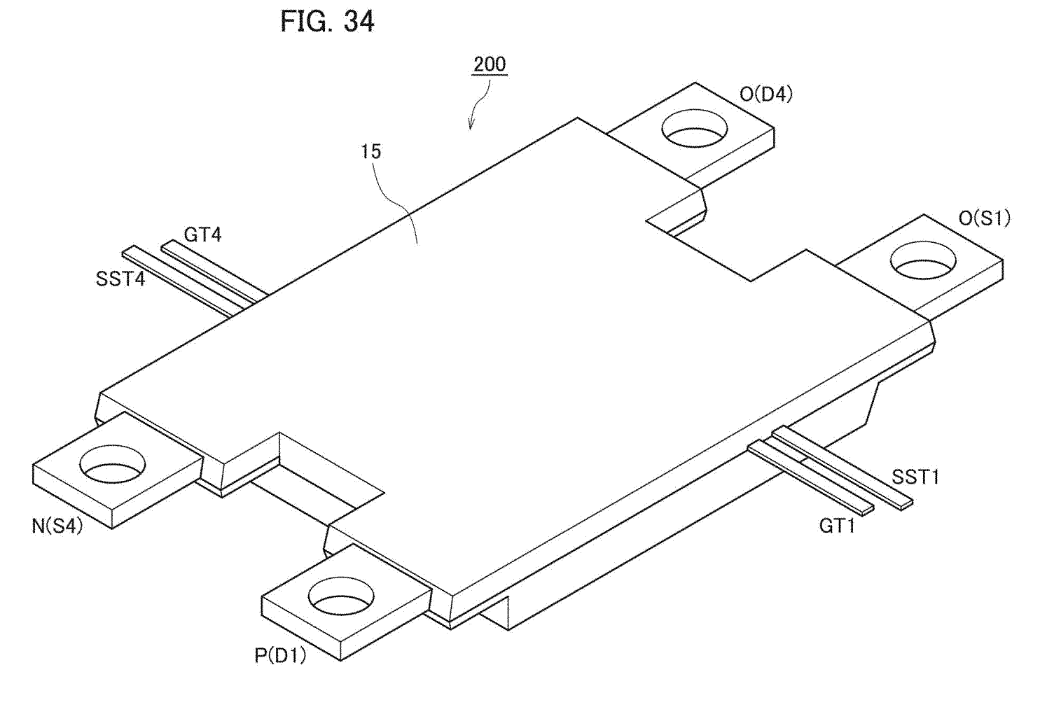

FIG. 32 shows a schematic planar pattern configuration before forming a second resin layer 15 in a 2-in-1 module (module with a built-in half-bridge), which is the semiconductor device 200 according to the embodiments, and FIG. 34 shows a schematic bird's-eye view configuration after forming the second resin layer 15. Moreover, FIG. 33 shows a circuit configuration of the 2-in-1 module (module with the built-in half-bridge) corresponding to FIG. 32 to which SiC MISFET is applied as a semiconductor chip, in the semiconductor device 200 according to the embodiments.

The semiconductor device 200 according to the embodiments includes a configuration of a module with the built-in half-bridge in which two MISFETs Q1, Q4 are built in one module.

FIG. 32 shows an example of 4-chip of the MISFETs Q1 and 4-chip of the MISFETs Q4 respectively disposed in parallel.

As shown in FIG. 34, the semiconductor device 200 according to the embodiments includes: a positive-side power terminal P and a negative-side power terminal N disposed at a first side of the ceramic substrate 8 covered with the second resin layer 15; a gate terminal GT1 and a source sense terminal SST1 disposed at a second side adjacent to the first side; an output terminal ◯ disposed at a third side opposite to the first side; and a gate terminal GT4 and a source sense terminal SST4 disposed at a fourth side opposite to the second side. In the embodiments, as shown in FIG. 32, the gate terminal GT1 and the source sense terminal SST1 are connected to the signal wiring pattern GL1 for gate and the signal wiring pattern SL1 for source in the MISFET Q1; and the gate terminal GT4 and the source sense terminal SST4 are connected to the signal wiring pattern GL4 for gate and the signal wiring pattern SL4 for source in the MISFET Q4.

As shown in FIG. 32, wires GW1, GW4 for gate and wires SSW1, SSW4 for source sense are connected towards the signal wiring patterns GL1, GL4 for gate and the signal wiring patterns SL1, SL4 for source sense which are disposed on the signal substrates 24₁, 24₄ from the MISFETs Q1, Q4. Moreover, gate terminals GT1, GT4 and source sense terminals SST1, SST4 for external extraction are respectively connected to the signal wiring patterns GL1, GL4 for gate and the signal wiring patterns SL1,SL4 for source sense by soldering etc.

As shown in FIG. 32, the signal substrates 24₁, 24₄ are connected by soldering etc. on the ceramics substrate 8.

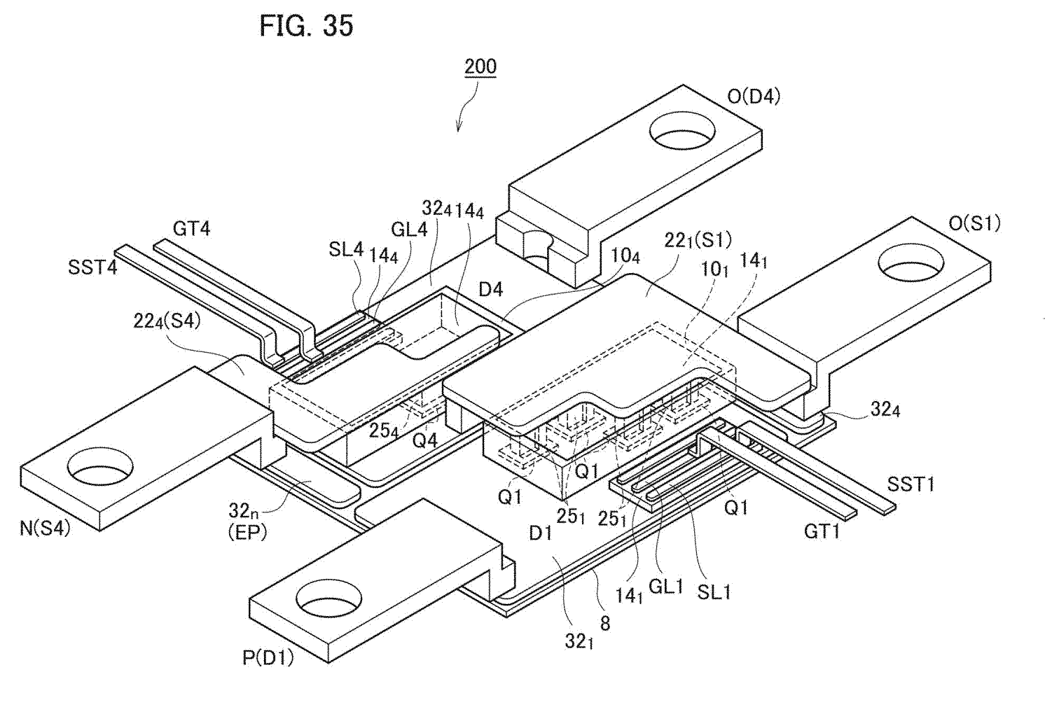

Moreover, FIG. 35 shows a schematic bird's-eye view configuration after forming upper surface plate electrodes 22₁, 22₄ and before forming the second resin layer 15, in a module with the built-in half-bridge, in the semiconductor device 200 according to the embodiments. The sources S1, S4 of 4 chips of the MISFETs Q1, Q4 respectively disposed in parallel are commonly connected with the upper surface plate electrodes 22₁, 22₄. Note that the wires GW1, GW4 for gate and the wires SSW1, SSW4 for source sense are not illustrated in FIG. 35.

Although illustration is omitted in FIGS. 32 to 35, the diodes may be connected reversely in parallel respectively between D1 and S1 and between D4 and S4 of the MISFETs Q1, Q4.

Although the sources S1, S4 of 4 chips of the MISFETs Q1, Q4 disposed in parallel are commonly connected with the upper surface plate electrodes 22₁, 22₄ in an example shown in FIGS. 32 to 35, the sources may be conducted to one another with the wire instead of the upper surface plate electrodes 22₁, 22₄.

The positive-side power terminal P and the negative-side power terminal N, and the gate terminals GT1, GT4 and the source sense terminals SST1, SST4 for external extraction can be formed of Cu, for example.

The signal substrates 24₁, 24₄ can be formed by including a ceramics substrate. The ceramic substrate may be formed by including Al₂O₃, AlN, SiN, AlSiC, or SiC of which at least the surface is insulation, for example.

Main wiring conductors (electrode patterns) 32₁, 32₄, 22ₙ can be formed by including Cu, Al, etc., for example.

Portions of pillar electrodes 25₁, 25₄ and upper surface plate electrodes 22₁, 22₄ configured to respectively connect between the sources S1, S4 of the MISFETs Q4, and the upper surface plate electrodes 22₁, 22₄ may be formed by including CuMo, Cu, or the like, for example. If materials having the same size and equivalent values of CTE are compared with each other, a generated stress of the material of which the Young's modulus is larger is larger. Accordingly, if materials of which the value of Young's modulus×CTE is smaller is selected, structural members having a smaller value of the generated stress can be obtained. CuMo has such an advantage. Moreover, although CuMo is inferior to Cu, the electric resistivity of CuMo is also relatively low. Moreover, a separation distance along the surface between the upper surface plate electrodes 22₁, 22₄ is called a creepage distance. A value of the creepage distance thereof is approximately 2 mm, for example.

The wires GW1 and GW4 for gate and the wires SSW1 and SSW4 for source sense can be formed by including Al, AlCu, or the like, for example.

SiC based power devices, e.g. SiC DIMISFET and SiC TMISFET, or GaN based power devices, e.g. GaN based High Electron Mobility Transistor (HEMT), are applicable, as the MISFETs Q1, Q4. In some instances, power devices, e.g. Si based MISFETs and IGBT, are also applicable thereto.

In the semiconductor device 200 according to the embodiments, 4 chips of the MISFETs Q1 are disposed via a bonding layer 2 under chip on a main wiring conductor (electrode pattern) 32₁ in a first vessel member 10₁ disposed via a soldering layer etc. on a main wiring conductor (electrode pattern) 32₁. Moreover, the first vessel member 10₁ is filled up with a first resin layer 14₁ in order to resin-seal the 4 chips of the MISFETs Q1. Similarly, 4 chips of the MISFETs Q4 are disposed via a bonding layer 2 under chip on a main wiring conductor (electrode pattern) 32₄ in a second vessel member 10₄ disposed via a soldering layer etc. on a main wiring conductor (electrode pattern) 32₄. Moreover, the second vessel member 10₄ is filled up with a first resin layer 14₄ in order to resin-seal the 4 chips of the MISFETs Q4. The first resin layer 14₁ and the first resin layer 14₄ are formed with the same material(s). Although the plurality of the MISFETs Q1, Q4 are respectively contained in the vessel members 10₁, 10₄ in the example shown in FIG. 32 and FIG. 35, the vessel members 10₁, 10₄ may be disposed so as to respectively contain a plurality of MISFETs Q1, Q4.

The principal portion of the semiconductor device 200 according to the embodiments includes: a ceramics substrate 8; semiconductor chips Q1, Q4 disposed on the ceramics substrate 8; vessel members 10₁, 10₄ disposed on the ceramics substrate 8, the vessel members 10₁, 10₄ configured to enclose the semiconductor chips Q1, Q4; fist resin layers 14₁, 14₄ respectively disposed inside the vessel members 10₁, 10₄, the fist resin layers 14₁, 14₄ configured to respectively seal the semiconductor chips Q1, Q4; and second resin layer 15 disposed on an outside of the vessel members 10₁, 10₄ and the first resin layers 14₁, 14₄, the second resin layer 15 configured to seal the first resin layers 14₁, 14₄ and the ceramics substrate 8.

### (Concrete Example of Semiconductor Device)

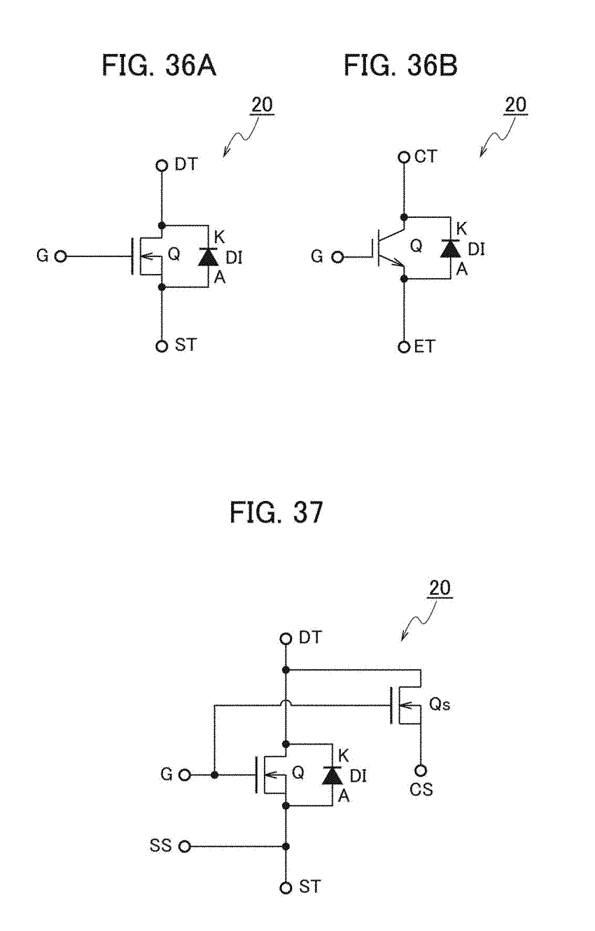

FIG. 36A shows a schematic circuit representative of an SiC MISFET of the 1-in-1 module, which is the semiconductor device 20 according to the embodiments. FIG. 36B shows a schematic circuit representation of the IGBT of the 1-in-1 module.

A diode DI connected in reversely parallel to the MISFET Q is shown in FIG. 36A. A main electrode of the MISFET Q is expressed with a drain terminal DT and a source terminal ST. Similarly, a diode DI connected in reversely parallel to the IGBT Q is shown in FIG. 36B. A main electrode of the IGBT Q is expressed with a collector terminal CT and an emitter terminal ET. Moreover, FIG. 37 shows a detailed circuit representative of the SiC MISFET of the 1-in-1 module, which is the semiconductor device 20 according to the embodiments.

The semiconductor device 20 according to the embodiments includes a configuration of 1-in-1 module, for example. More specifically, one piece of the MISFET Q is included in one module. As an example, five chips (MISFET×5) can be mounted thereon, and a maximum of five pieces of the MISFETs Q respectively can be connected to one another in parallel. Note that it is also possible to mount a part of five pieces of the chips for the diode DI thereon.

More particularly, as shown in FIG. 37, a sense MISFET Qs is connected to the MISFETQ in parallel. The sense MISFET Qs is formed as a miniaturized transistor in the same chip as the MISFET Q. In FIG. 37, reference numeral SS denotes a source sense terminal, reference numeral CS denotes a current sense terminal, and reference numeral G denotes a gate signal terminal. Note that, also in the semiconductor chip Q according to the embodiments, the sense MISFET Qs is formed as a minuteness transistor in the same chip.

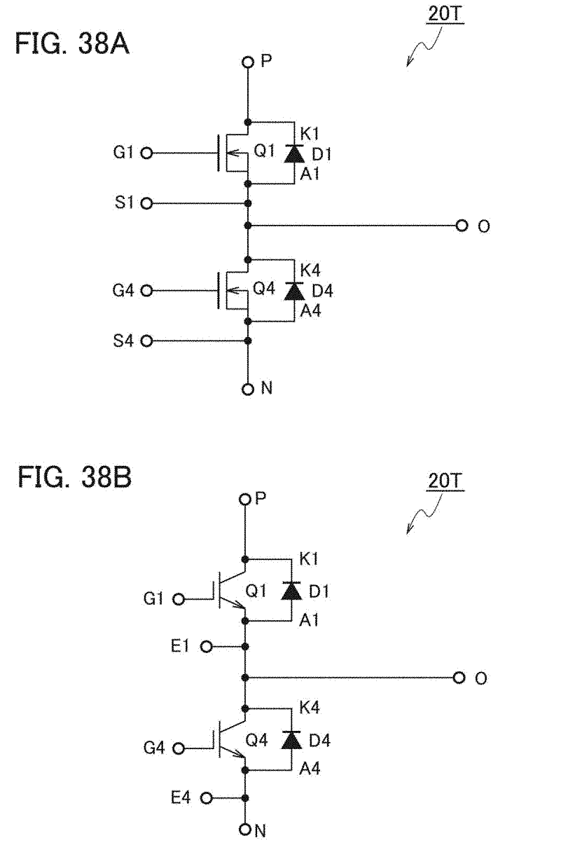

Moreover, FIG. 38A shows a schematic circuit representative of the SiC MISFET of the 2-in-1 module, which is the semiconductor device 20T according to the embodiments.

As shown in FIG. 38A, two MISFETs Q1, Q4, and diodes D1, D4 connected in reversely parallel to the MISFETs Q1, Q4 are built in one module. Reference numeral G1 denotes a gate signal terminal of the MISFET Q1, and reference numeral S1 denotes a source terminal of the MISFET Q1. Reference numeral G4 denotes a gate signal terminal of the MISFET Q4, and reference numeral S4 denotes a source terminal of the MISFET Q4. Reference numeral P denotes a positive side power input terminal, reference numeral N denotes a negative side power input terminal, and reference numeral 0 denotes an output terminal.

Moreover, FIG. 38B shows a schematic circuit representative of the IGBT of the 2-in-1 module, which is the semiconductor device 20T according to the embodiments. As shown in FIG. 38B, two IGBTs Q1, Q4, and diodes D1, D4 connected in reversely parallel to the IGBTs Q1, Q4 are built in one module. Reference numeral G1 denotes a gate signal terminal of the IGBT Q1, and reference numeral E1 denotes an emitter terminal of the IGBT Q1. Reference numeral G4 denotes a gate signal terminal of the IGBT Q4, and reference numeral E4 denotes an emitter terminal of the IGBT Q4. Reference numeral P denotes a positive side power input terminal, reference numeral N denotes a negative side power input terminal, and reference numeral 0 denotes an output terminal.

### (Configuration Example of Semiconductor Chip)

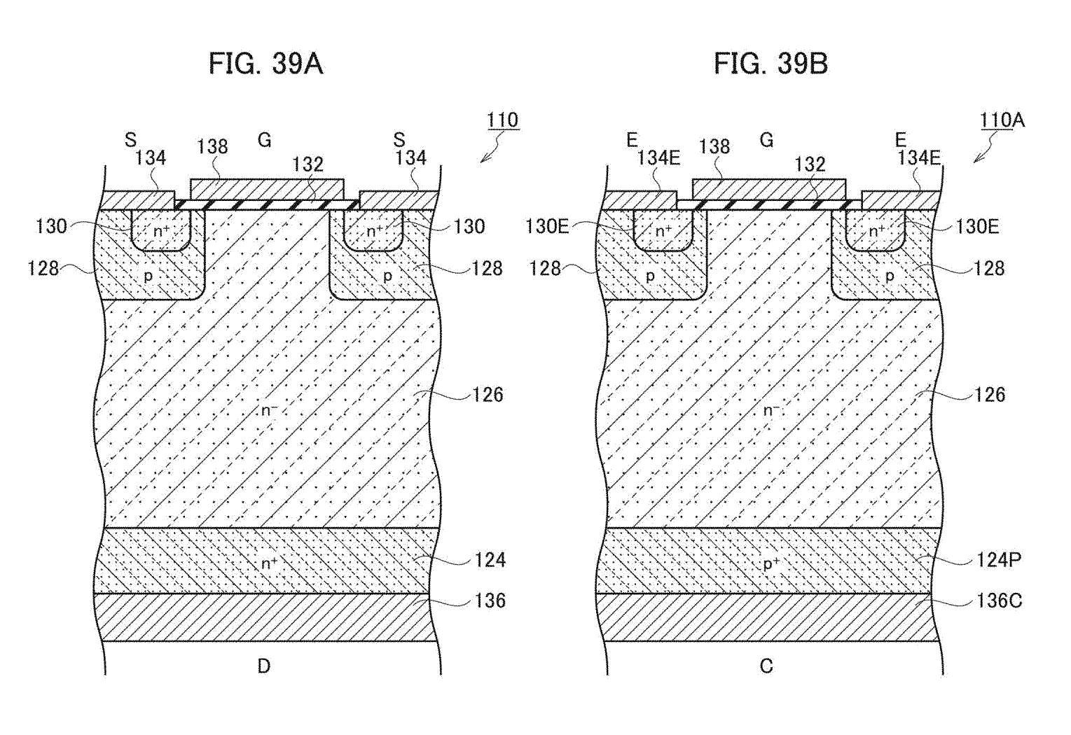

FIG. 39A shows a schematic cross-sectional structure of an SiC MISFET, which is an example of a semiconductor chip which can be applied to the power module according to the embodiments, and FIG. 39B shows a schematic cross-sectional structure of the IGBT.

As shown in FIG. 39A, a schematic cross-sectional structure of the SiC MISFET as an example of the semiconductor chip 110 (Q) which can be applied to the embodiments includes: a semiconductor substrate 126 composed by including an n⁻type high resistivity layer; a p body region 128 formed on a front surface side of the semiconductor substrate 126; a source region 130 formed on a front side surface of the p body region 128; a gate insulating film 132 disposed on a front side surface of the semiconductor substrate 126 between the p body regions 128; a gate electrode 138 disposed on the gate insulating film 132; a source electrode 134 connected to the source region 130 and the p body region 128; an n⁺drain region 124 disposed on a back side surface opposite to the surface of the semiconductor substrate 126; and a drain electrode 136 connected to the n⁺type drain area 124.

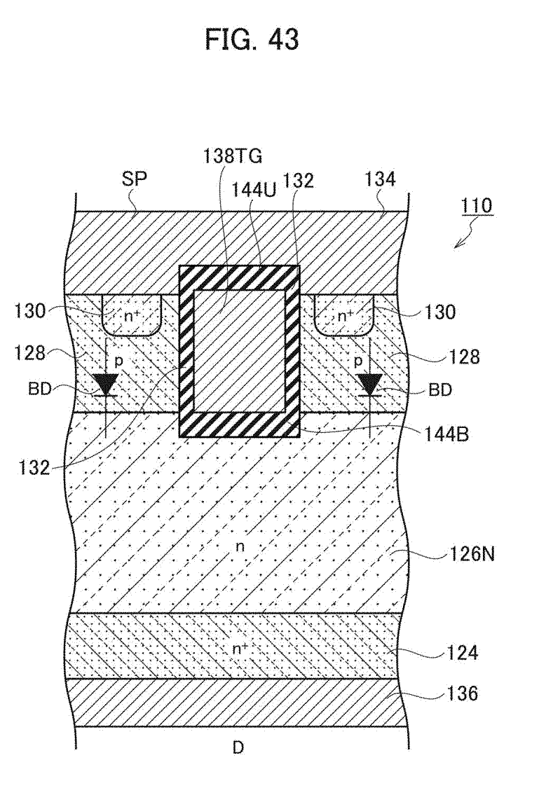

Although the semiconductor chip 110 is composed by including a planar-gate-type n channel vertical SiC-MISFET in FIG. 39A, the semiconductor device 110 may be composed by including an n channel vertical SiC-TMISFET, etc., shown in FIG. 43 mentioned below.

Moreover, a GaN based FET etc. instead of SiC MISFET can also be adopted to the semiconductor chip 110 (Q) which can be applied to the embodiments.

Any one of an SiC based power device or a GaN based power device can be adopted to the semiconductor chip 110 applicable to the embodiments.

Furthermore, a semiconductor of which the bandgap energy is within a range from 1.1 eV to 8 eV, for example, can be used for the semiconductor chip 110 applicable to the embodiments.

Similarly, as shown in FIG. 39B, the IGBT as an example of the semiconductor chip 110A (Q) applicable to the embodiments includes: a semiconductor substrate 126 composed by including an n⁻type high resistivity layer; a p body region 128 formed on a front surface side of the semiconductor substrate 126; an emitter region 130E formed on a front side surface of the p body region 128; a gate insulating film 132 disposed on a front side surface of the semiconductor substrate 126 between the p body regions 128; a gate electrode 138 disposed on the gate insulating film 132; an emitter electrode 134E connected to the emitter region 130E and the p body region 128; a p⁺collector region 124P disposed on a back side surface opposite to the surface of the semiconductor substrate 126; and a collector electrode 136C connected to the p⁺collector region 124P.

In FIG. 39B, although the semiconductor chip 110A is composed by including a planar-gate-type n channel vertical IGBT, the semiconductor device 110A may be composed by including a trench-gate-type n channel vertical IGBT, etc.

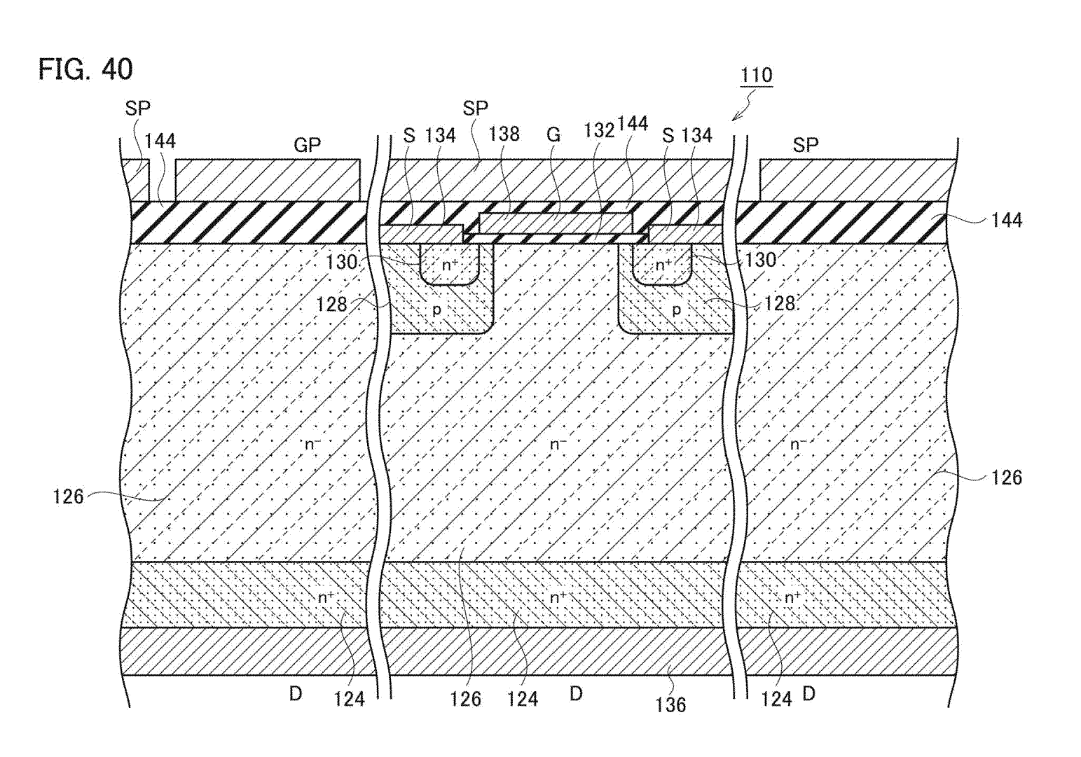

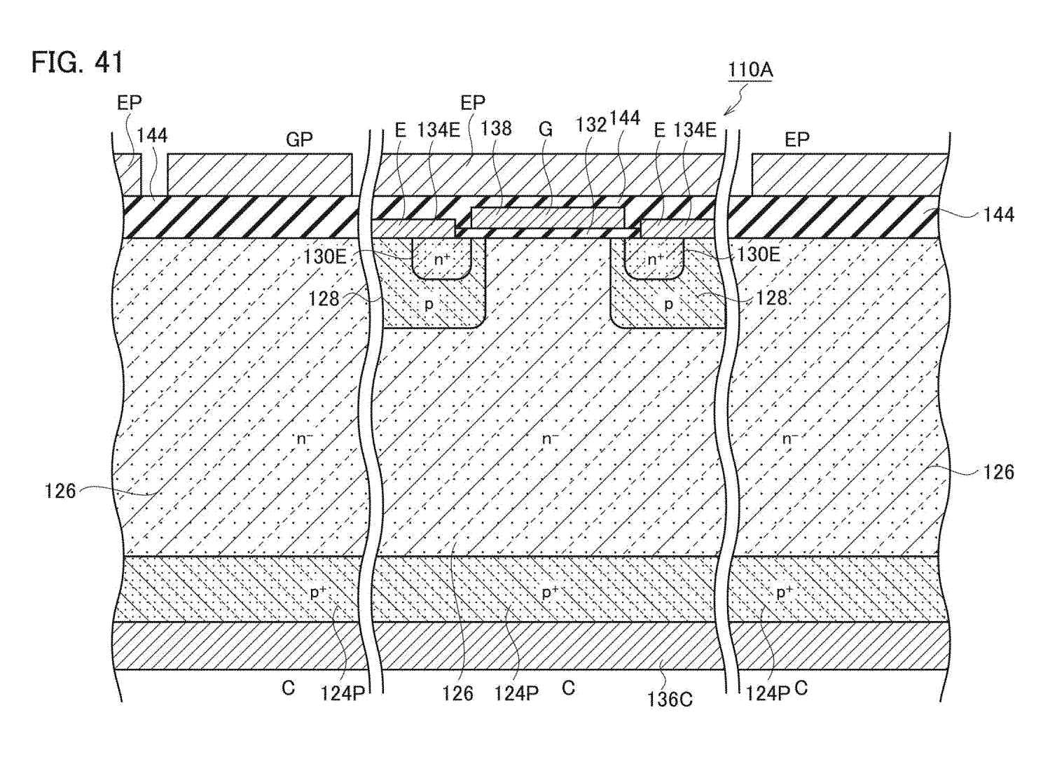

FIG. 40 shows a schematic cross-sectional structure of an SiC MISFET including a source pad electrode SP and a gate pad electrode GP, which is an example of the semiconductor chip 110 applicable the embodiments. The gate pad electrode GP is connected to the gate electrode 138 disposed on the gate insulating film 132, and the source pad electrode SP is connected to the source electrode 134 connected to the source region 130 and the p body region 128.

Moreover, as shown in FIG. 40, the gate pad electrode GP and the source pad electrode SP are disposed on an interlayer insulating film 144 for passivation which covers the surface of the semiconductor chip 110. Microstructural transistor structure may be formed in the semiconductor substrate 126 below the gate pad electrode GP and the source pad electrode SP in the same manner as the center portion shown in FIG. 39A or 40.

Furthermore, as shown in FIG. 40, the source pad electrode SP may be disposed to be extended onto the interlayer insulating film 144 for passivation, also in the transistor structure of the center portion.

FIG. 41 shows a schematic cross-sectional structure of an IGBT including an emitter pad electrode EP and a gate pad electrode GP, which is an example of the semiconductor chip 110A to be applied to the embodiments. The gate pad electrode GP is connected to the gate electrode 138 disposed on the gate insulating film 132, and the emitter pad electrode EP is connected to the emitter electrode 134E connected to the emitter region 130E and the p body region 128.

Moreover, as shown in FIG. 41, the gate pad electrode GP and the emitter pad electrode EP are disposed on an interlayer insulating film 144 for passivation which covers the surface of the semiconductor chip 110A. Microstructural IGBT structure may be formed in the semiconductor substrate 126 below the gate pad electrode GP and the emitter pad electrode EP in the same manner as the center portion shown in FIG. 39B or 41.

Furthermore, as shown in FIG. 41, the emitter pad electrode EP maybe disposed to be extended onto the interlayer insulating film 144 for passivation, also in the IGBT structure of the center portion.

### SiC DIMISFET

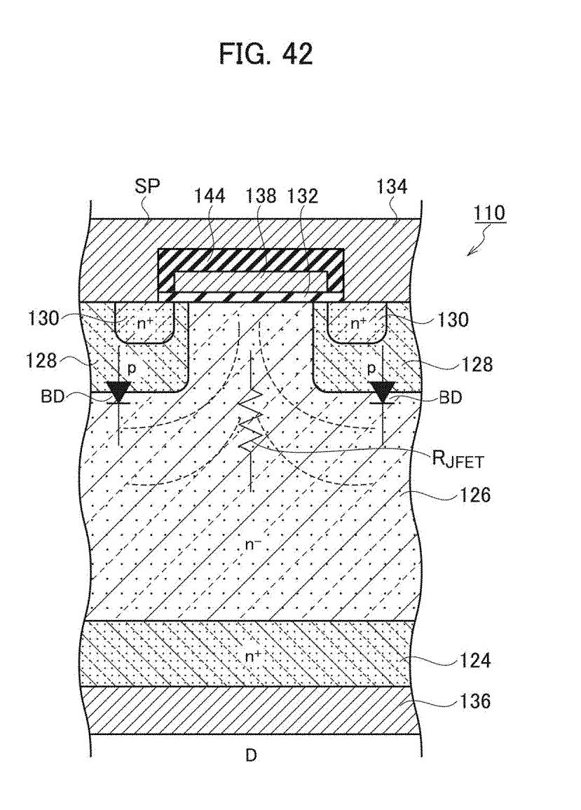

FIG. 42 shows a schematic cross-sectional structure of an SiC DIMISFET, which is an example of the semiconductor chip 110 which can be applied to the embodiments.

As shown in FIG. 42, the SiC DIMISFET applicable to the embodiments includes: a semiconductor substrate 126 composed of an n⁻type high resistivity layer; a p body region 128 formed on a front surface side of the semiconductor substrate 126; an n⁺source region 130 formed on a front side surface of the p body region 128; a gate insulating film 132 disposed on a front side surface of the semiconductor substrate 126 between the p body regions 128; a gate electrode 138 disposed on the gate insulating film 132; a source electrode 134 connected to the source region 130 and the p body region 128; an n⁺drain region 124 disposed on a back side surface opposite to the surface of the semiconductor substrate 126; and a drain electrode 136 connected to the n⁺type drain area 124.

In the semiconductor chip 110 shown in FIG. 42, the p body region 128 and the n⁺source region 130 formed on the front side surface of the p body region 128 are formed with double ion implantation (DI), and the source pad electrode SP is connected to the source region 130 and the source electrode 134 connected to the p body region 128. A gate pad electrode GP (not shown) is connected to the gate electrode 138 disposed on the gate insulating film 132. Moreover, as shown in FIG. 42, the source pad electrode SP and the gate pad electrode GP (not shown) are disposed on an interlayer insulating film 144 for passivation configured to cover the front side surface of the semiconductor chip 110.

As shown in FIG. 42, in the SiC DIMISFET, since a depletion layer as shown with the dashed lines is formed in the semiconductor substrate 126 composed of a n⁻type high resistivity layer inserted into the p body regions 128, channel resistance R_{JFET} accompanying the junction type FET (JFET) effect is formed. Moreover, as shown in FIG. 42, body diodes BD are respectively formed between the p body regions 128 and the semiconductor substrates 126.

### SiC TMISFET

FIG. 43 shows a schematic cross-sectional structure of an SiC TMISFET, which is an example of the semiconductor chip 110 which can be applied to the embodiments.

As shown in FIG. 43, the SiC TMISFET applicable to the embodiments includes: a semiconductor substrate 126N composed of an n⁻type high resistivity layer; a p body region 128 formed on a front surface side of the semiconductor substrate 126N; an n⁺source region 130 formed on a front side surface of the p body region 128; a trench gate electrode 138TG passing through the p body region 128, the trench gate electrode 138TG formed in the trench formed up to the semiconductor substrate 126N via the gate insulating layer 132 and the interlayer insulating films 144U, 144B; a source electrode 134 connected to the source region 130 and the p body region 128; an n⁺type drain area 124 disposed on a back side surface of the semiconductor substrate 126N opposite to the front side surface thereof; and a drain electrode 136 connected to the n⁺type drain area 124.

In the semiconductor chip 110 shown in FIG. 43, a trench gate electrode 138TG passes through the p body region 128, and the trench gate electrode 138TG formed in the trench formed up to the semiconductor substrate 126N is formed via the gate insulating layer 132 and the interlayer insulating films 144U, 144B, and the source pad electrode SP is connected to the source region 130 and the source electrode 134 connected to the p body region 128. A gate pad electrode GP (not shown) is connected to the trench gate electrode 138TG disposed on the gate insulating film 132. Moreover, as shown in FIG. 43, the source pad electrode SP and the gate pad electrode GP (not shown) are disposed on an interlayer insulating film 144U for passivation configured to cover the front side surface of the semiconductor chip 110.

In the SiC TMISFET, channel resistance R_{JFET} accompanying the junction type FET (JFET) effect as the SiC DIMISFET is not formed. Moreover, body diodes BD are respectively formed between the p body regions 128 and the semiconductor substrates 126N.

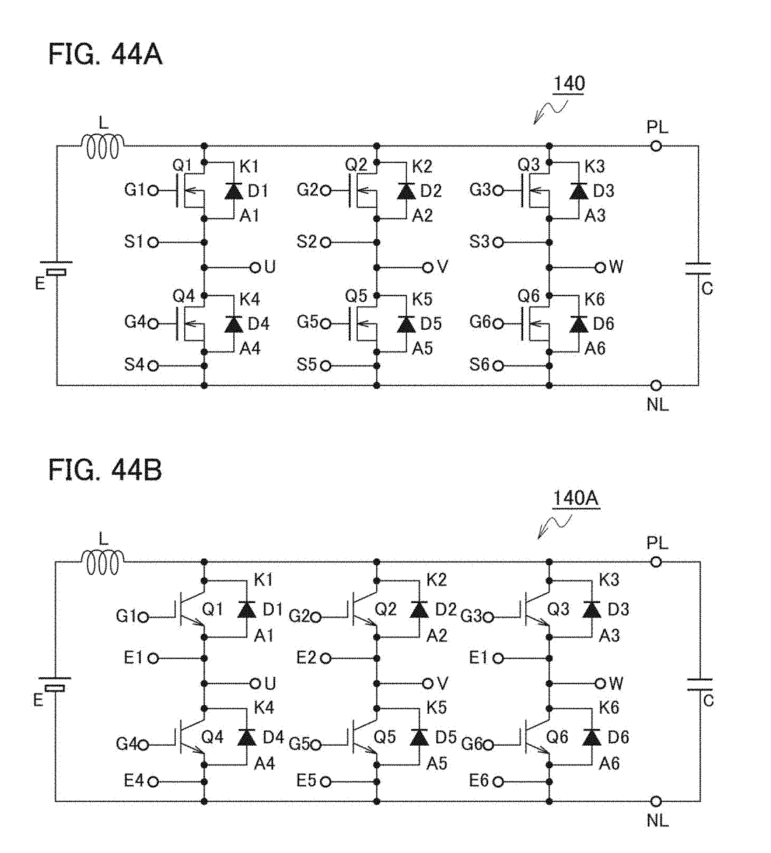

FIG. 44A shows an example of a circuit configuration in which the SiC MISFET is applied as a semiconductor chip, and a snubber capacitor C is connected between the power terminal PL and the earth terminal (ground terminal) NL, in a schematic circuit configuration of a three-phase AC inverter 140 composed using the semiconductor device according to the embodiments. Similarly, FIG. 44B shows an example of a circuit configuration in which the IGBT is applied as a semiconductor chip, and a snubber capacitor C is connected between the power terminal PL and the earth terminal (ground terminal) NL, in a schematic circuit configuration of a three-phase AC inverter 140A composed using the semiconductor device according to the embodiments.

When connecting the semiconductor device according to the embodiments to the power source E, large surge voltage Ldi/dt is produced by an inductance L included in a connection line due to a high switching speed of the SiC MISFET and IGBT. For example, the surge voltage Ldi/dt is expressed as follows: Ldi/dt=3×10⁹ (A/s), where a current change di=300 A, and a time variation accompanying switching di/dt=100 ns. Although a value of the surge voltage Ldi/dt changes dependent on a value of the inductance L, the surge voltage Ldi/dt is superimposed on the power source V. Such a surge voltage Ldi/dt can be absorbed by the snubber capacitor C connected between the power terminal PL and the earth terminal (ground terminal) NL.

### (Application Examples for Applying Semiconductor Device)

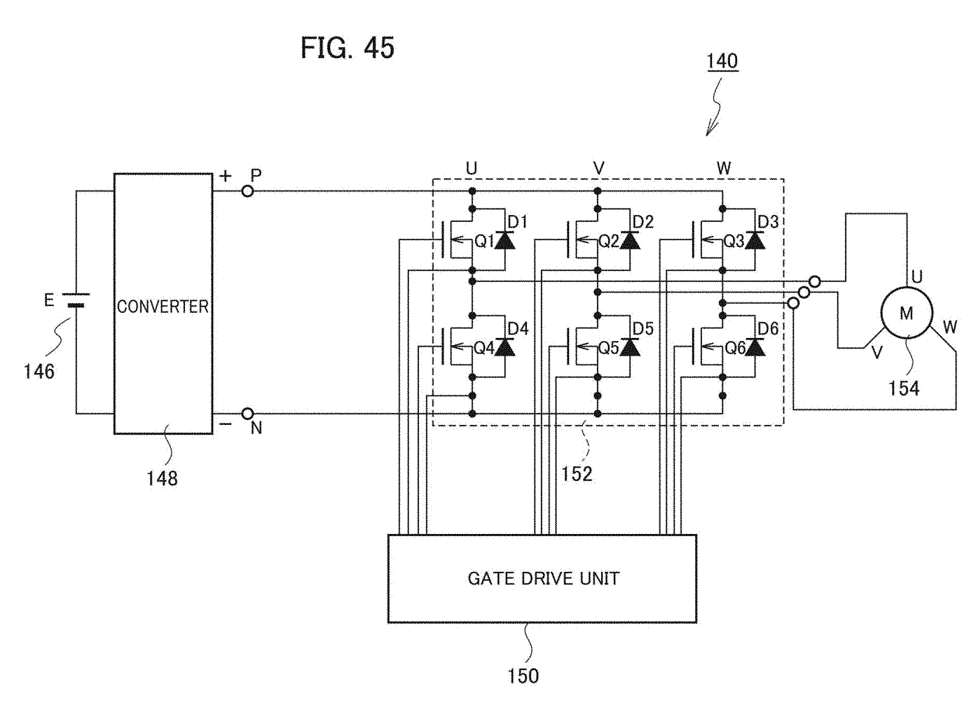

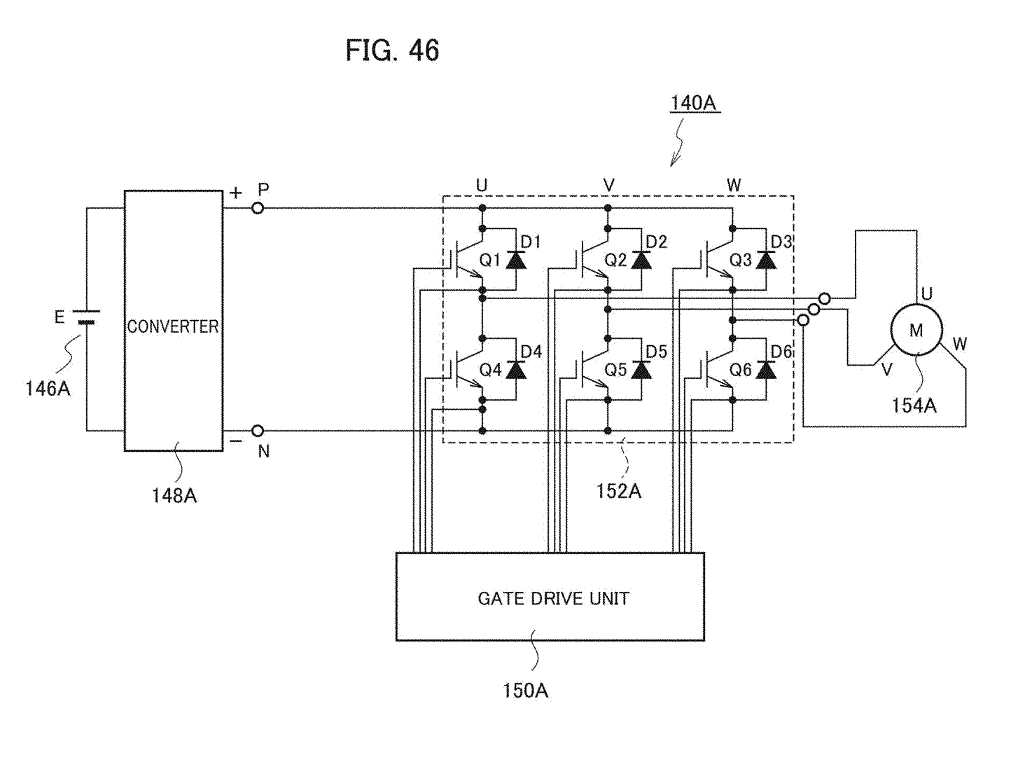

Next, there will now be explained the three-phase AC inverter 140 composed using the semiconductor device 20T according to the embodiments to which the SiC MISFET is applied as the semiconductor chip, with reference to FIG. 45.

As shown in FIG. 45, the three-phase AC inverter 140 includes a gate drive unit 150, a semiconductor device unit 152 connected to the gate drive unit 150, and a three-phase AC motor unit 154. U-phase, V-phase, and W-phase inverters are respectively connected to the three-phase AC motor unit 154 so as to correspond to U phase, V phase, and W phase of the three-phase AC motor unit 154, in the semiconductor device unit 152. In the embodiments, the gate drive unit 150 is connected to the SiC MISFETs Q1, Q4, SiC MISFETs Q2, Q5, and the SiC MISFETs Q3, Q6.

The semiconductor device unit 152 includes the SiC MISFETs Q1, Q4, and Q2, Q5, and Q3, Q6 having inverter configurations connected between a positive terminal (+) and a negative terminal (−) of the converter 148 to which a storage battery (E) 146 is connected. Moreover, flywheel diodes D1-D6 are respectively connected reversely in parallel between the source and the drain of the SiC MISFETs Q1-Q6.

Next, there will now be explained the three-phase AC inverter 140A composed using the semiconductor device 20T according to the embodiments to which the IGBT is applied as the semiconductor chip, with reference to FIG. 46.

As shown in FIG. 46, the three-phase AC inverter 140A includes a gate drive unit 150A, a semiconductor device unit 152A connected to the gate drive unit 150A, and a three-phase AC motor unit 154A. U-phase, V-phase, and W-phase inverters are respectively connected to the three-phase AC motor unit 154A so as to correspond to U phase, V phase, and W phase of the three-phase AC motor unit 154A, in the semiconductor device unit 152A. In this case, the gate drive unit 150A is connected to the IGBTs Q1, Q4, IGBTs Q2, Q5, and the IGBTs Q3, Q6.

The semiconductor device unit 152A includes the IGBTs Q1, Q4, and Q2, Q5, and Q3, Q6 having inverter configurations connected between a positive terminal (+) and a negative terminal (−) of the converter 148A to which a storage battery (E) 146A is connected. Furthermore, flywheel diodes D1-D6 are respectively connected reversely in parallel between the emitter and the collector of the IGBTs Q1-Q6.

The semiconductor device or the power module according to the embodiments can be formed as any one selected from the group consist of 1-in-1 module, 2-in-1 module, 4-in-1 module, 6-in-1 module, and 7-in-1 module.

To the semiconductor device or the power module according to the embodiments, a structure of putting a shielding plate thereon after a primary mold, and then also performing an secondary mold may be applied. An electromagnetic noise can be reduced by adopting such a configuration thereinto.

As explained above, according to the embodiments, there can be provided the semiconductor device, the power module and the fabrication method thereof, capable of reducing the thermal resistance to improve the current density by reducing the warpage of the semiconductor device, and capable of realizing cost reduction and miniaturization thereof by reducing the number of chips.

### Other Embodiments

As explained above, the embodiments have been described, as a disclosure including associated description and drawings to be construed as illustrative, not restrictive. This disclosure makes clear a variety of alternative embodiments, working examples, and operational techniques for those skilled in the art.

Such being the case, the embodiments cover a variety of embodiments, whether described or not.

### INDUSTRIAL APPLICABILITY

The semiconductor device and the power module according to the embodiments can be used for manufacturing techniques of semiconductor modules, e.g. IGBT modules, diode modules, and MOS modules (Si, SiC, GaN), and can be applied to wide applicable fields, e.g. inverters used for HEV/EV, inverters and converters used for industrial equipment.

What is claimed is:

1. A semiconductor device comprising:
a substrate;
at least one semiconductor chip disposed on the substrate;
a first resin layer disposed on the semiconductor chip, the first resin layer formed so as to cover the substrate and the semiconductor chip; and
a second resin layer disposed on the first resin layer, the second resin layer having a CTE smaller than a CTE of the first resin layer and having a coefficient of elasticity larger than a coefficient of elasticity of the first resin layer, wherein
the second resin layer is formed so as to cover at least an upper surface of the first resin layer.

2. The semiconductor device according to claim 1, wherein
the first resin layer and the second resin layer respectively comprises hard resins.

3. The semiconductor device according to claim 1, wherein
the substrate comprises a substrate selected from the group consisting of a copper substrate, and a ceramics substrate having a copper foil formed on a surface of the ceramics substrate.

4. The semiconductor device according to claim 1, wherein
each of the CTE of the first resin layer and the CTE of the second resin layer is larger than a CTE of the substrate.

5. The semiconductor device according to claim 1, wherein
the thickness of the first resin layer is formed so as to be lower than a height of the semiconductor chip.

6. The semiconductor device according to claim 1, further comprising:
a third resin layer inserted between the first resin layer and the second resin layer, wherein
a CTE of the third resin layer is smaller than the CTE of the first resin layer but is larger than the CTE of the second resin layer, and
a coefficient of elasticity of the third resin layer is larger than the coefficient of elasticity of the first resin layer but is smaller than the coefficient of elasticity of the second resin layer.

7. The semiconductor device according to claim 1, further comprising:
a fourth resin layer inserted between the first resin layer and the second resin layer, wherein
the fourth resin layer contains a resin used for the first resin layer is mixed with a resin used for the second resin layer, wherein
a CTE of the fourth resin layer is smaller than the CTE of the first resin layer but is larger than the CTE of the second resin layer, and
a coefficient of elasticity of the fourth resin layer is larger than the coefficient of elasticity of the first resin layer but is smaller than the coefficient of elasticity of the second resin layer.

8. The semiconductor device according to claim 1, wherein
each of a filler contained in the first resin layer and a filler of the second resin layer is equal to or greater than 50 vol %.

9. The semiconductor device according to claim 1, wherein
a thickness of the first resin layer is thinner than a thickness of the second resin layer.

10. A power module comprising a plurality of semiconductor devices, the semiconductor device comprising:
a substrate;
at least one semiconductor chip disposed on the substrate;
a first resin layer disposed on the semiconductor chip, the first resin layer formed so as to cover the substrate and the semiconductor chip; and
a second resin layer disposed on the first resin layer, the second resin layer having a CTE smaller than a CTE of the first resin layer and having a coefficient of elasticity larger than a coefficient of elasticity of the first resin layer, wherein
the second resin layer is formed so as to cover at least an upper surface of the first resin layer.

11. A power module comprising:
a semiconductor device; and
a cooling apparatus bonded on a lower surface of the semiconductor device via a bonding layer for cooling apparatus, wherein
the semiconductor device comprises:
a substrate;
at least one semiconductor chip disposed on the substrate;
a first resin layer disposed on the semiconductor chip, the first resin layer formed so as to cover the substrate and the semiconductor chip; and
a second resin layer disposed on the first resin layer, the second resin layer having a CTE smaller than a CTE of the first resin layer and having a coefficient of elasticity larger than a coefficient of elasticity of the first resin layer, wherein
the second resin layer is formed so as to cover at least an upper surface of the first resin layer.

12. The power module according to claim 10, wherein
the first resin layer and the second resin layer respectively comprising hard resins.

13. The power module according to claim 10, wherein
the substrate comprises a substrate selected from the group consisting of a copper substrate, and a ceramics substrate having a copper foil formed on a surface of the ceramics substrate.

14. The power module according to claim 10, wherein
each of the CTE of the first resin layer and the CTE of the second resin layer is larger than a CTE of the substrate.

15. The power module according to claim 10, wherein
the thickness of the first resin layer is formed so as to be lower than a height of the semiconductor chip.

16. The power module according to claim 10, further comprising:
a third resin layer inserted between the first resin layer and the second resin layer, wherein
a CTE of the third resin layer is smaller than the CTE of the first resin layer but is larger than the CTE of the second resin layer, and
a coefficient of elasticity of the third resin layer is larger than the coefficient of elasticity of the first resin layer but is smaller than the coefficient of elasticity of the second resin layer.

17. The power module according to claim 10, further comprising:
a fourth resin layer inserted between the first resin layer and the second resin layer, wherein
the fourth resin layer contains a resin used for the first resin layer is mixed with a resin used for the second resin layer, wherein
a CTE of the fourth resin layer is smaller than the CTE of the first resin layer but is larger than the CTE of the second resin layer, and
a coefficient of elasticity of the fourth resin layer is larger than the coefficient of elasticity of the first resin layer but is smaller than the coefficient of elasticity of the second resin layer.

18. The power module according to claim 10, wherein
each of a filler contained in the first resin layer and a filler of the second resin layer is equal to or greater than 50 vol %.

19. The power module according to claim 11, wherein
the cooling apparatus comprising a cooling apparatus selected from the group consisting of a water-cooling type and an air-cooling type cooling apparatus.

20. The power module according to claim 10, wherein
a thickness of the first resin layer is thinner than a thickness of the second resin layer.
